(19) United States
(12) Patent Application Publication
(10) Pub. No.: US 2011/0242145 A1
(43) Pub. Date: Oct. 6, 2011

(54) DISPLAY DEVICE, DIFFERENTIAL AMPLIFIER, AND DATA LINE DRIVE METHOD FOR DISPLAY DEVICE

(75) Inventors: Kouichi NISHIMURA, Kanagawa (JP); Masamitsu NAKAOKA, Kanagawa (JP)

(73) Assignee: RENESAS ELECTRONICS CORPORATION, Kawasaki-shi (JP)

(21) Appl. No.: 13/074,818

(22) Filed: Mar. 29, 2011

(30) Foreign Application Priority Data
Mar. 30, 2010 (JP) 2010-076838

(51) Int. Cl. G09G 5/10; H03F 3/45

(52) U.S. Cl. 345/690; 330/257

(57) ABSTRACT

A display device is provided with a plurality of differential amplifiers associated with a plurality of data lines within a display panel. Each of the plurality of differential amplifiers includes: an output stage circuit including a first transistor having a source connected to the positive power supply and a second transistor having a source connected to the negative power supply, an output terminal connected to drains of the first and second transistors; and a bias control circuit provided between the adder circuit and the output stage circuit to achieve bias control of gates of the first and second transistors. During the switching period, the output stage circuit provides short-circuiting between the gate and source of each of the first and second transistors, and the bias control circuit cuts off a current path between the gates of the first and second transistors during the switching period.

### INCORPORATION BY REFERENCE

This application claims the benefit of priority based on Japanese Patent Application No. 2010-076838, filed on Mar. 30, 2010, the disclosure of which is incorporated herein by reference.

### BACKGROUND OF THE INVENTION

1. Field of the Invention

The present invention relates to a display device, and more particularly, to a differential amplifier circuit in a source driver of a display device.

2. Description of the Related Art

In recent years, the number of products using a liquid crystal panel, such as liquid crystal televisions and cellular phones and the like has been increased. Further, the demand for the large-sized thin type flat panel is also increased, and a semiconductor integrated circuit that controls display of a liquid crystal panel is required to realize smooth display of moving pictures and to drive a large number of data lines.

Japanese Patent Application Publication No. 2007-052396 A (patent literature 1), which may be related to the present invention, discloses a liquid crystal display device. In the following, a description is given of the liquid crystal display device of patent literature 1 with reference to the attached drawings. FIG. 1 is a diagram showing the configuration of the liquid crystal display device disclosed in patent literature 1. The liquid crystal display device shown in FIG. 1 is adapted to dot inversion driving. Referring to FIG. 1, the liquid crystal display device disclosed in patent literature 1 is provided with a liquid crystal panel 22, and a data line drive circuit 25 that outputs gray-level voltages to data lines of the liquid crystal panel 22.

The liquid crystal panel 22 has a configuration in which liquid crystal is filled between a TFT (Thin Film Transistor) array substrate and an opposite substrate (not shown) opposed thereto. Provided on the TFT array substrate are scan lines extending in the horizontal direction (one of which is denoted by the numeral 16), and data lines 14a to 14d and 15a to 15d extending in the vertical direction. TFTs 12a to 12h are respectively provided at the intersections of the scan line 16 and the data lines 14a to 14d and 15a to 15d. Hereinafter, the data lines 14a to 14d may be referred to as odd-numbered data lines and the data lines 15a to 15d may be referred to as even-numbered data lines.

Also, a plurality of pixel electrodes are arranged in rows and columns at the intersections of the scan lines and the data lines 14a to 14d and 15a to 15d. The gates, sources, and drains of the TFTs 12a to 12h are respectively connected to the scan line 16, the data lines 14a to 14d and 15a to 15d, and the pixel electrodes.

On the other hand, a common electrode and color filters for R (red), G (green), and B (blue) are formed on the opposite substrate. In an actual implementation, the common electrode is formed as a transparent electrode formed over the entire surface of the opposite substrate so as to be opposed to the pixel electrodes. The respective scan lines are supplied with scan signals, and the TFTs 12a to 12h connected to the scan line 16 are simultaneously turned on when the scan line 16 is selected by the corresponding scan signal. The data lines 14a to 14d and 15a to 15d are supplied with gray-level voltages, and charges are accumulated in the corresponding pixel electrodes depending on the gray-level voltages. Depending on the potential difference between the common electrode and a pixel electrode to which a gray-level voltage is written, the arrangement of the liquid crystal between the common electrode and the pixel electrode is changed. This allows controlling the transmission amount of light incident from a backlight (not shown). Each pixel of the liquid crystal panel 22 provides various shades of displays based on gray-levels of R, G, and B colors, depending on the transmitted light amount.

The data line drive circuit 25 is provided with: a positive-side gray-level voltage generator circuit 23, a negative-side gray-level voltage generator circuit 24, positive-side DA conversion circuits (hereinafter referred to as positive-side DACs) 1a to 1d, negative-side DA conversion circuits (hereinafter referred to as negative-side DACs) 2a to 2d, a switching section 17, a buffer section 18, an output switching section 19, an output short-circuiting section 20, and a common node 21.

The outputs of the gray-level voltage generator circuits 23 and 24 are connected to the DACs 1a to 1d and 2a to 2d, and the outputs of the DACs 1a to 1d and 2a to 2d are connected to the switching section 17 is provided. The outputs of the switching section 17 are connected to the buffer section 18, and the outputs of the buffer section 18 are connected to the output switching section 19. The outputs of the output switching section 19 are connected to the output short-circuiting section 20.

Next, a description is given of the operation of the liquid crystal display device disclosed in Patent literature 1, which has the configuration as described above. FIG. 2 is a timing chart illustrating the operation of the liquid crystal display device in Patent literature 1.

In FIG. 2, a strobe signal is used to control output switches 8a to 8d and 9a to 9d within the switching section 19, and the common node connecting switches 10a to 10d and short-circuiting switches 11a to 11d within the output short-circuiting section 20. A polarity inversion signal POL is used to control first switches 3a to 3d, second switches 4a to 4d, third switches 5a to 5d, and fourth switches 6a to 6d within the switching section 17. In FIG. 2, the odd-numbered output V₂ₙ₋₁ represents an exemplary waveform of the gray-level voltage outputted to one of the data odd-numbered lines 14a to 14d and the even-numbered output V₂ₙ represents an exemplary waveform of gray-level voltages outputted to one of the even-numbered data lines 15a to 15d. It should be noted that the description of FIG. 2 will be given on an assumption that the gray-level voltages outputted to the data lines 14a to 14d are same, and those outputted to the data lines 15a to 15d are same.

Referring to FIG. 2, gray-level voltage output periods during which a positive or negative gray-level voltage is outputted to achieve a normal display operation and switching periods during which the data lines are neutralized to a voltage level near the common electrode level Vcom (the voltage level of the common electrode on the opposite substrate) are repeated.

When the polarity inversion signal POL is pulled up to the high level, the first switches 3a to 3d and fourth switches 6a to 6d are turned on, and the second switches 4a to 4d and third switches 5a to 5d are turned off. As a result, the positive-side DACs 1a to 1d are connected to differential amplifiers 7a, 7c, 7e, and 7g, and the negative-side DACs 2a to 2d are connected to differential amplifiers 7b, 7d, 7f, and 7h. This results in that the connections of the odd-numbered data lines 14a to 14d are switched from the negative-side DACs 2a to 2d to the positive-side DACs 1a to 1d, and the connections of the even-numbered data lines 15a to 15d are switched from the positive-side DACs 1a to 1d to the negative-side DACs 2a to 2d.

Also, when the strobe signal STB is pulled up to the high level simultaneously with the pull-up of the polarity inversion signal POL, the output switches 8a to 8d and output switches 9a to 9d are turned off, and the common node connecting switches 10a to 10d and short-circuiting switches 11a to 11d are turned on. As a result, the differential amplifiers 7a to 7h are disconnected from the respective data lines 14a to 14d and 15a to 15d. Also, the pairs of the odd-numbered data lines 14a to 14d and the corresponding even-numbered data lines 15a to 15d are respectively short-circuited by the short-circuiting switches 11a to 11d. Furthermore, the odd-numbered data lines 14a to 14d and the even-numbered data lines 15a to 15d are short-circuited to the common node by the common node connecting switches 10a to 10d. As a result, all of the data lines 14a to 14d and 15a to 15d are commonly short-circuited to the common node 21, so that the voltage levels thereof are cancelled out and averaged to a voltage level near the common electrode level Vcom during the switching period.

When the strobe signal STB is then pulled down to the low level, the output switches 8a to 8d and output switches 9a to 9d are turned on, and the common node connecting switches 10a to 10d and short-circuiting switches 11a to 11d are turned off. As a result, the gray-level voltages of predetermined polarities are outputted to the respective data lines 14a to 14d and 15a to 15d from the differential amplifiers 7a to 7h during the first gray-level voltage output period.

Subsequently, when the polarity inversion signal POL is pulled down to the low level, the first switches 3a to 3d and fourth switches 6a to 6d are turned off, and the second switches 2a to 2b and third switches 5a to 5d are turned on. As a result, the positive-side DACs 1a to 1d are connected to the differential amplifiers 7b, 7d, 7f, and 7h, and the negative-side DACs 2a to 2d are connected to the differential amplifiers 7a, 7c, 7e, and 7g. This results in that the connections of the odd-numbered data lines 14a to 14d are switched from the positive-side DACs 1a to 1d to the negative-side DACs 2a to 2d, and the connections of the even-numbered data lines 15a to 15d are switched from the negative-side DACs 2a to 2d to the positive-side DACs 1a to 1d.

When the strobe signal STB is then pulled up to the high level simultaneously with the pull-down of the polarity inversion signal POL, the output switches 8a to 8d and output switches 9a to 9d are turned off, and the common node connecting switches 10a to 10d and short-circuiting switches 11a to 11d are turned on. As a result, the differential amplifiers 7a to 7h are disconnected from the respective data lines 14a to 14d and 15a to 15d. Also, the pairs of the odd-numbered data lines 14a to 14d and the corresponding even-numbered data lines 15a to 15d are respectively short-circuited by the short-circuiting switches 11a to 11d. Furthermore, the odd-numbered data lines 14a to 14d and the even-numbered data lines 15a to 15d are commonly connected to the common node by the common node connecting switches 10a to 10d. As a result, all of the data lines 14a to 14d and 15a to 15d are connected to the common node 21 and thereby short-circuited, so that the voltage levels thereof are cancelled out and averaged to a voltage level near the common electrode level Vcom (switching period).

When the strobe signal STB is then pulled down to the low level, the output switches 8a to 8d and output switches 9a to 9d are turned on, and the common node connecting switches 10a to 10d and short-circuiting switches 11a to 11d are turned off. As a result, the gray-level voltages of the opposite polarities are outputted to the respective data lines 14a to 14d and 15a to 15d from the differential amplifiers 7a to 7h during the second gray-level voltage output period.

As thus described, the liquid crystal display device of Patent literature 1 is configured to average the voltages of the data lines 14a to 14d and 15a to 15d to an intermediate voltage level near the common electrode level Vcom, each when the polarities of the gray-level voltages outputted from the odd-numbered output V₂ₙ₋₁ and the even-numbered output V₂ₙ are switched to each other in response to the polarity inversion signal POL. This effectively reduces charges to be supplied to the pixel electrodes from the differential amplifiers 7a to 7h in supplying the gray-level voltages to the respective data lines 14a to 14d and 15a to 15d, since this only requires supplying charges so as to change from the intermediate level voltage to the predetermined gray-level voltages. In other words, power consumption necessary for implementing dot inversion is effectively reduced, since changes in the gray-level voltages to be written by the differential amplifiers 7a to 7h are reduced in writing the gray-level voltages to the respective data lines 14a to 14d and 15a to 15d.

Japanese Patent No. 3,520,106 (patent literature 2), which may be related to the present invention, discloses a typical differential amplifier. In the following, a description is given of the differential amplifier disclosed in patent literature 2 with reference to the attached drawings. FIG. 3 is a diagram illustrating the configuration of the differential amplifier disclosed in patent literature 2. The differential amplifier shown in FIG. 3 is configured as a rail-to-rail amplifier including an AB class drive circuit and an adder circuit which are coupled to each other.

Referring to FIG. 3, an input stage circuit of the differential amplifier is provided with: a first differential input stage circuit including a pair of input transistors QI1 and QI2 having sources commonly connected to the positive power supply VDD through a current source 100; and a second differential input stage circuit including a pair of input transistors QI3 and QI4 having commonly connected sources. The gates of the input transistors QI1 and QI3 are commonly connected to an input terminal 110, and the gates of the transistors QI2 and QI4 are commonly connected to an input terminal 120.

The adder circuit 140 is provided with transistors QS1 to QS8, and a current source 150 which operates as a floating current source generating a current I_{S}. Respective output currents of the four transistors QI1 to QI4 are added together by the adder circuit 140. The upper half of the adder circuit 140 is provided with: the two transistors QS1 and QS5 that are connected in series between the positive power supply VDD and a terminal 160 of the current source 150; and the transistor pair QS2 and QS6 that are connected in series between the positive power supply VDD and a terminal 170. The respective gates of the transistors QS1 and QS2 are commonly connected to the terminal 160, directly. The respective gates of the transistors QS5 and QS6 are commonly connected to a terminal that supplies a bias voltage VS1.

The common connecting point between the transistors QS1 and QS5, denoted by the symbol “A”, is connected to the drain of the input transistor QI3 through an interconnection line (not shown). This interconnection line is indicated by another symbol “A” indicating a connecting point connected to the drain of the transistor QI3. Similarly, a common connecting point B between the transistors QS2 and QS6 is connected to the drain of the input transistor QI4. This connection is indicated by the symbol “B”. The upper half of the adder circuit 140 configures a current mirror.

The lower half of the adder circuit 140 is provided with: the transistors QS7 and QS3 that are connected in series between a terminal 180 of the current source 150 and a negative power supply VSS; and the transistors QS8 and QS4 that are connected in series between a terminal 190 of the adder circuit 140 and the negative power supply VSS. The respective gates of the transistors QS3 and QS4 are commonly connected to the terminal 180. Also, the respective gates of the transistors QS7 and QS8 are commonly connected to a terminal that supplies a bias voltage VS2.

A common connecting point C between the transistors QS7 and QS3, and a common connecting point D between the transistors QS8 and QS4 are respectively connected to the drains of the input transistors QI1 and QI2 as indicated by the symbols “C” and “D”. The lower half of the adder circuit 140 also configures a current mirror.

An AB class bias control circuit and rail-to-rail output stage, which is denoted by the numeral 200 is connected to the terminals 170 and 190. The AB class bias control circuit and rail-to-rail output stage 200 is provided with transistors QD1 to QD8, output transistors QO1 and QO2, and a current source 210. The output current is drawn from an output terminal 220. The complementary pair of transistors QD1 and QD2 constituting the AB bias control circuit is connected in parallel to each other, i.e., connected to the terminals 170 and 190 in a reversely symmetric form, to respectively determine the gate voltages of the output transistors QO1 and QO2.

The output transistors QO1 and QO2 are connected in series between the positive power supply VDD and the negative power supply VSS and the respective drains thereof are commonly connected to the output terminal 220. The gate of the output transistor QO1 is connected to the terminal 170, and the gate of the output transistor QO2 is connected to the terminal 190. The diode-connected transistors QD3 and QD4 and the current source 210 are connected in series between the positive power supply VDD and the negative power supply VSS. The transistors QD5 and QD6 and the diode-connected transistors QD7 and QD8 are connected in series between the positive power supply VDD and the negative power supply VSS. The gate of the transistor QD5 is connected to the gate of the transistor QD3, and the gate of the transistor QD6 is connected to the gate of the transistor QD4.

The respective output currents of the four input transistors QI4 to QI4 are added together in the adder circuit 140 that includes the transistors QS1 to QS8. The transistors QS1 and QS2, and QS3 and QS4, which constitute current mirrors provide mirroring for the currents at the circuit points A and C to generate a drive current which is the currents at the circuit points A and C and the currents at the circuit points B and C added together, and provide the drive current for the rail-to-rail output stage 200. The current source 150 keeps a constant bias current to compensate the output impedance of the AB class bias control circuit.

The above-described techniques suffer from a problem of image quality deterioration resulting from a considerably-large on-resistance of the output switch 19 which causes delay of data writing onto the data lines in relation to the increase in panel size of a display device and the increase in scanning speed. The increase in size of a thin type flat panel causes the increase in the load capacitance of the data lines 14a to 14d and 15a to 15d of the liquid panel 22 illustrated in FIG. 1. Further, the time duration of each horizontal synchronization period is decreased as the vertical synchronization frequency is increased. Under such circumstances, an increase in the time constant of the data line load including the on-resistances of the output switches 8a to 8d and 9a to 9d causes a significant problem. The output characteristics of the gray-level voltages to be supplied to the data lines 14a to 14d and 15a to 15d are deteriorated, even if the outputs of the positive-side DACs 1a to 1d, negative-side DACs 2a to 2d, or differential amplifiers 7a to 7h are ideal pulse outputs, and this undesirably hinders properly displaying images and deteriorates the image quality.

### SUMMARY

In an aspect of the present invention, a display device is provided with: a plurality of differential amplifiers associated with a plurality of data lines within a display panel, the plurality of differential amplifiers respectively receiving gray-level voltages which are switched between positive and negative polarities with respect to a reference voltage level and outputting the received gray-level voltages to associated ones of the plurality of data lines; and an output short-circuiting section providing short-circuiting among the plurality of data lines during a switching period in which polarities of the gray-level voltages to be received by the plurality of differential amplifiers are switched. Each of the plurality of differential amplifiers includes: an input circuit including a first differential input stage circuit comprising a first transistor pair and a second differential input stage circuit comprising a second transistor pair, the first and second transistor pairs being complementary; an adder circuit including a first current mirror circuit provided between the first differential input stage circuit and a positive power supply and a second current mirror circuit provided between the second differential input stage circuit and a negative power supply; an output stage circuit including a first transistor having a source connected to the positive power supply, a second transistor having a source connected to the negative power supply, an output terminal connected to drains of the first and second transistors, a first phase compensation capacitor provided between the first current mirror circuit and the output terminal, and a second phase compensation capacitor provided between the second current mirror circuit and the output terminal; and a bias control circuit provided between the adder circuit and the output stage circuit to achieve bias control of gates of the first and second transistors. During the switching period, the output stage circuit provides short-circuiting between the gate and source of the first transistor and short-circuiting between the gate and source of the second transistor, and charges or discharges the first and second phase compensation capacitors to a certain voltage level. The bias control circuit cuts off a current path between the gates of the first and second transistors during the switching period.

In another aspect of the present invention, a differential amplifier is provided with: an input circuit including a first differential input stage circuit comprising a first transistor pair and a second differential input stage circuit comprising a second transistor pair, the first and second transistor pairs being complementary; an adder circuit including a first current mirror circuit provided between the first differential input stage circuit and a positive power supply and a second current mirror circuit provided between the second differential input stage circuit and a negative power supply; an output stage circuit including a first transistor having a source connected to the positive power supply, a second transistor having a source connected to the negative power supply, an output terminal connected to drains of the first and second transistors, a first phase compensation capacitor provided between the first current mirror circuit and the output terminal, and a second phase compensation capacitor provided between the second current mirror circuit and the output terminal; and a bias control circuit provided between the adder circuit and the output stage circuit to achieve bias control of gates of the first and second transistors. During a switching period, the output stage circuit provides short-circuiting between the gate and source of the first transistor and short-circuiting between the gate and source of the second transistor, and charges or discharges the first and second phase compensation capacitors to a certain voltage level. The bias control circuit cuts off a current path between the gates of the first and second transistors during the switching period.

In still another aspect of the present invention, provided is a data line drive method for a display device including: a plurality of differential amplifiers associated with a plurality of data lines within a display panel, the plurality of differential amplifiers respectively receiving gray-level voltages which are switched between positive and negative polarities with respect to a reference voltage level and outputting the received gray-level voltages to associated ones of the plurality of data lines; and an output short-circuiting section providing short-circuiting among the plurality of data lines during a switching period in which polarities of the gray-level voltages to be received by the plurality of differential amplifiers are switched. Each of the plurality of differential amplifiers including: an input circuit including a first differential input stage circuit comprising a first transistor pair and a second differential input stage circuit comprising a second transistor pair, the first and second transistor pairs being complementary; an adder circuit including a first current mirror circuit provided between the first differential input stage circuit and a positive power supply and a second current mirror circuit provided between the second differential input stage circuit and a negative power supply; an output stage circuit including a first transistor having a source connected to the positive power supply, a second transistor having a source connected to the negative power supply, an output terminal connected to drains of the first and second transistors, a first phase compensation capacitor provided between the first current mirror circuit and the output terminal, and a second phase compensation capacitor provided between the second current mirror circuit and the output terminal; and a bias control circuit provided between the adder circuit and the output stage circuit to achieve bias control of gates of the first and second transistors. The data line drive method includes: short-circuiting the gate and source of each of the first and second transistors during the switching period; charging or discharging the first and second phase compensation capacitors to a certain voltage level during the switching period; and cutting off a current path between the gates of the first and second transistors during the switching period.

The present invention provides a display device which effectively prevents image quality deterioration even if the panel size and the horizontal synchronization frequency are increased.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a diagram illustrating the configuration of the liquid crystal display device disclosed in patent literature 1;

FIG. 2 is a timing chart illustrating the operation of the liquid crystal display device disclosed in patent literature 1;

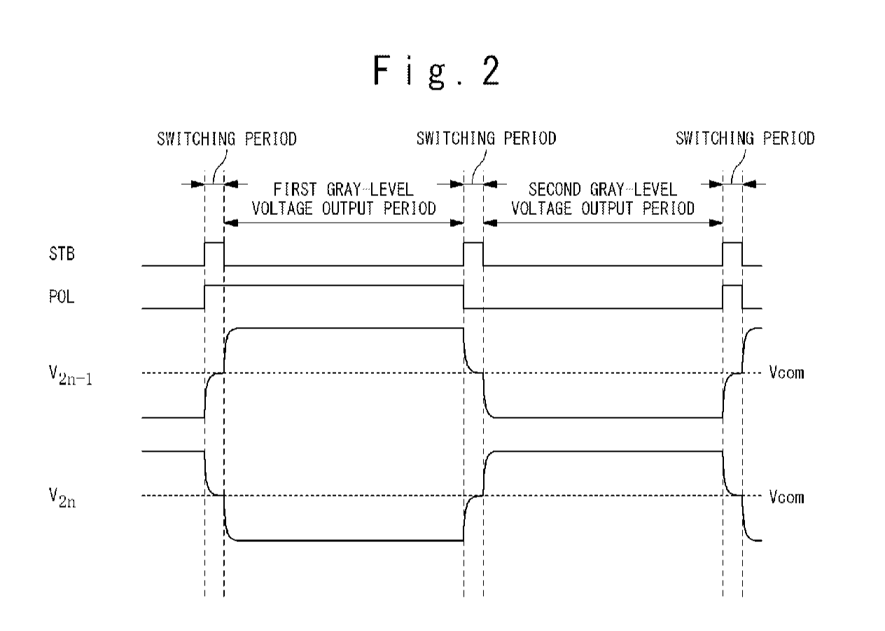

FIG. 3 is a diagram illustrating the configuration of the differential amplifier disclosed in Patent literature 2;

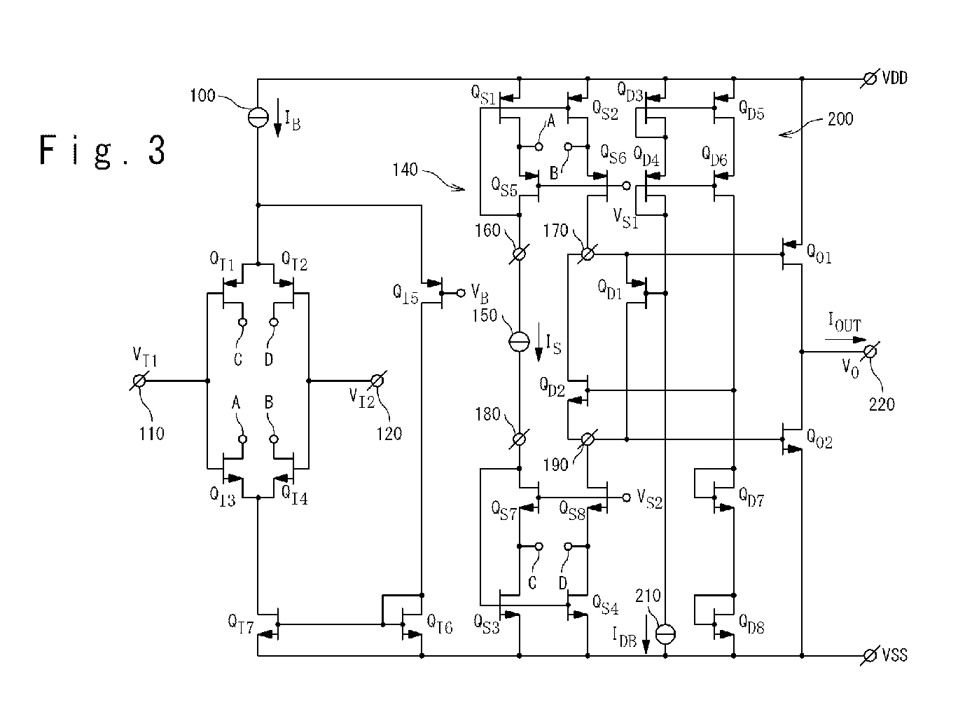

FIG. 4 is a diagram illustrating an exemplary configuration of a display device in a first embodiment of the present invention;

FIG. 5 is a diagram illustrating an exemplary configuration of a differential amplifier in the first embodiment of the present invention;

FIG. 6 is a diagram illustrating an exemplary configuration of a bias circuit in the first embodiment of the present invention;

FIG. 7 is a timing chart showing an exemplary operation of the display device in the first present embodiment of the present invention;

FIG. 8 is a diagram illustrating an exemplary configuration of a differential amplifier in a second embodiment of the present invention;

FIG. 9 is a diagram illustrating an exemplary configuration of a differential amplifier in a third embodiment of the present invention;

FIG. 10 is a timing chart showing an exemplary operation of a display device in the third embodiment of the present invention;

FIG. 11 is a diagram illustrating an exemplary configuration of a differential amplifier in a fourth embodiment of the present invention; and

FIG. 12 is a diagram illustrating an exemplary configuration of a differential amplifier in a fifth embodiment of the present invention.

### DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

### Device Configuration

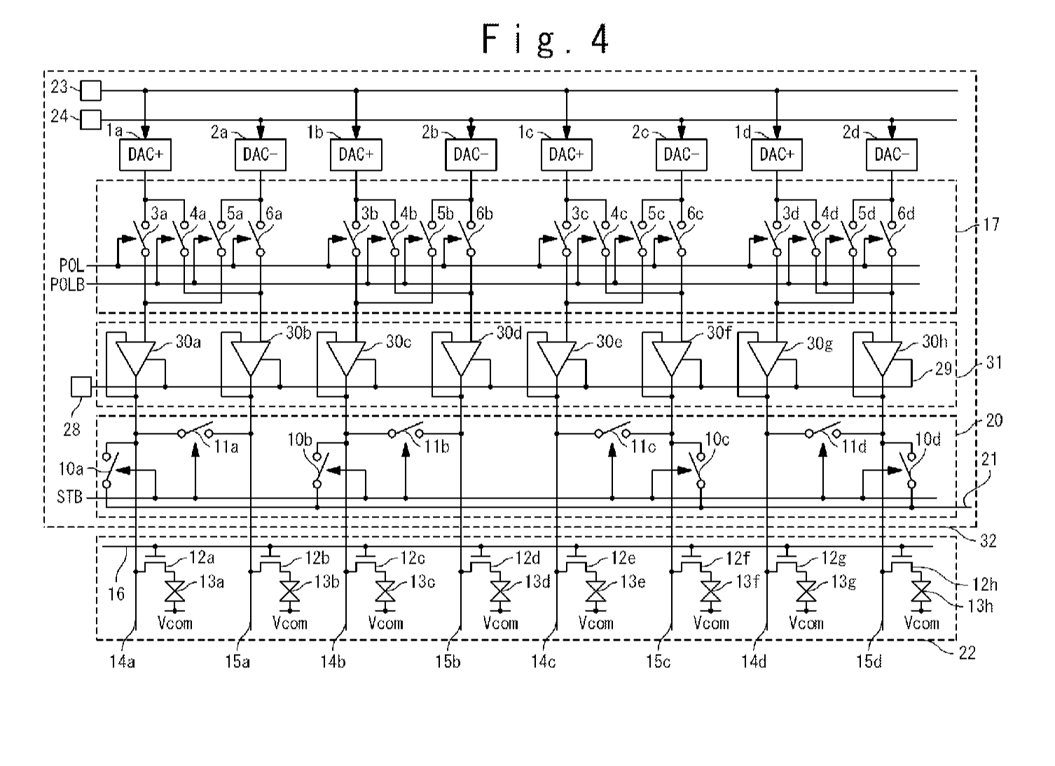

First, a description is given of an exemplary configuration of a display device in a first embodiment with an example of an active matrix type liquid crystal display device adapted to dot inversion driving. FIG. 4 is a diagram illustrating the configuration of the display device of this embodiment. The display device of this embodiment is provided with a liquid crystal panel 22 and a data line drive circuit 32. It should be noted that FIG. 4 only shows pixels arranged in one row and eight columns pixels for simplicity. Also, illustrations are omitted for a scan line drive circuit that supplies scan signals, a backlight illuminating the back surface of the liquid crystal panel 22, and other components.

First, a description is given of the liquid crystal panel 22. The liquid crystal panel 22 has a display region including a plurality of pixels in which an image is displayed. In the liquid crystal panel 22, liquid crystal is filled between a TFT array substrate and an opposite substrate (not shown) opposed thereto.

Provided on the TFT array substrate are scan lines extending in the horizontal direction (one of which are denoted by the numeral 16), and data lines 14a to 14d and 15a to 15d extending in the vertical direction, and TFTs 12a to 12h are respectively provided at the intersections of the scan line 16 and the data lines 14a to 14d and 15a to 15d. In the following, the data lines 14a to 14d may be referred to as the odd-numbered data lines and the data lines 15a to 15d may be referred to as the even-numbered data lines. Also, a plurality of pixel electrodes are arranged in a matrix form at the intersections of the scan lines and the data lines 14a to 14d and 15a to 15d. The gates, sources and drains of the TFTs 12a to 12h are respectively connected to the scan line 16, the data lines 14a to 14d and 15a to 15d, and the pixel electrodes.

Provided on the opposite substrate are a common electrode and color filters of R (red), G (green), and B (blue) color. In an actual implementation, the common electrode is a transparent electrode that is formed to cover the entire surface of the opposite substrate and opposed to the pixel electrodes. The respective scan lines are supplied with scan signals, and all the TFTs 12a to 12h connected to the scan line 16 are simultaneously turned on when the scan line 16 is selected by the corresponding scanning signals. Each of the data lines 14a to 14d and 15a to 15d is supplied with a gray-level voltage, and charges are accumulated on each pixel electrode depending on the corresponding gray-level voltage.

Depending on the potential difference between the common electrode and a pixel electrode to which the gray-level voltage is written, the arrangement of the liquid crystal between the pixel electrode and the common electrode is changed. This allows controlling the transmission amount of light incident from the backlight (not shown). Each pixel of the liquid crystal panel 22 provides various shades of displays based on gray-levels of R, G, and B colors, depending on the transmitted light amount.

Liquid crystal capacitors 13a to 13h are formed of the pixel electrodes, the common electrode and the liquid crystal filled therebetween. Each of the liquid capacitors 13a to 13h is connected to the drain electrode of the corresponding TFT at one terminal thereof and to the common electrode at the other terminal thereof.

When the dot inversion driving is implemented, the polarities of the display signals supplied to the pixel electrodes are inverted for pixels adjacent along each of the data lines and pixels adjacent along each of the scan lines provided, within the liquid crystal panel 22. Also, the polarities of the display signals are switched for each image display, i.e., for every frame period. It should be noted that, hereinafter, a state where the polarity of a display signal is “positive (+)” refers to a state where the voltage level of the display signal is higher than the common electrode level Vcom, which is used as a reference level. On the other hand, a state where the polarity of a display signal is “negative (−)” refers to a state where the voltage of the display signal is lower than the common electrode level Vcom.

Next, a description is given of the data line drive circuit 32. The data line drive circuit 32 generates a set of gray-level voltages in response to externally inputted display signals (not shown). For achieving the dot inversion driving, the data line drive circuit 32 is fed with positive-side and negative-side display signals. The data line drive circuit 32 is provided with a positive-side gray-level voltage generator circuit 23, a negative-side gray-level voltage generator circuit 24, a positive-side DA conversion circuits (hereinafter referred to as positive-side DACs) 1a to 1d, negative-side DA conversion circuits (hereinafter referred to as negative-side DACs) 2a to 2d, a switching section 17, a buffer section 31, an output short-circuiting section 20, a common node 21, a bias circuit 28, and a bias bus 29.

The DACs 1a to 1d and DACs 2a to 2d are respectively connected to the outputs of the positive-side gray-level voltage generator circuit 23 and the negative-side gray-level voltage generator circuit 24. The switching section 17 is connected to the outputs of the DACs 1a to 1d and 2a to 2d. The buffer section 31 is connected with the outputs of the switching section 17 and also connected to the output of the bias circuit 28. The output short-circuiting section 20 is connected to the outputs of the buffer section 31.

The switching section 17 is provided with first switches 3a to 3d, second switches 4a to 4d, third switches 5a to 5d, and fourth switches 6a to 6d. The buffer section 31 is provided with differential amplifiers 30a to 30h. The output short-circuiting section 20 is provided with common node connecting switches 10a to 10d and short-circuiting switches 11a to 11d.

The positive-side gray-level voltage generator circuit 23 generates a set of positive-side gray-level voltages having different voltage levels of the “positive” polarity with respect to the common electrode level Vcom. The positive-side gray-level voltage generator circuit 23 is connected to the positive-side DACs 1a to 1d. The positive-side gray-level voltage generator circuit 23 feeds the positive-side gray-level voltages to the positive-side DACs 1a to 1d.

The negative-side gray-level voltage generator circuit 24 generates a set of negative-side gray-level voltages having different voltage levels of the “negative” polarity with respect to the common electrode level Vcom. The negative-side gray-level voltage generator circuit 24 is connected to the negative-side DACs 2a to 2d. The negative-side gray-level voltage generator circuit 24 feeds the negative-side gray-level voltages to the negative-side DACs 2a to 2d.

The positive-side DACs 1a to 1d externally receive display signals (not shown) and also receive the positive-side gray-level voltages from the positive-side gray-level voltage generator circuit 23. The positive-side DACs 1a to 1d select the positive-side gray-level voltages having levels corresponding to the display signals from the receives positive-side gray-level voltages, respectively. The positive-side DACs 1a to 1d are respectively connected to the differential amplifiers 30a, 30c, 30e, and 30g through the first switches 3a to 3d. Also, the positive-side DACs 1a to 1d are respectively connected to the differential amplifiers 30b, 30d, 30f, and 30h through the second switches 4a to 4d. The positive-side DACs 1a to 1d respectively feeds the positive-side gray-level voltages of the selected levels to the differential amplifiers 30a, 30c, 30e, and 30g through the first switches 3a to 3d, or to the differential amplifiers 30b, 30d, 30f, and 30h through the second switches 4a to 4d.

The negative-side DACs 2a to 2d externally receive display signals (not shown) and also receive the negative-side gray-level voltages from the negative-side gray-level voltage generator circuit 24. The negative-side DACs 2a to 2d select the negative-side gray-level voltages having voltage levels corresponding to the display signals from the negative-side gray-level voltages, respectively. The negative-side DACs 2a to 2d are respectively connected to the differential amplifiers 30a, 30c, 30e, and 30g through the third switches 5a to 5d. Also, the negative-side DACs 2a to 2d are respectively connected to the differential amplifiers 30b, 30d, 30f, and 30h through the fourth switches 6a to 6d. The negative-side DACs 2a to 2d respectively feed the negative-side gray-level voltages having the selected levels to the differential amplifiers 30a, 30c, 30e, and 30g through the third switches 5a to 5d, or to the differential amplifiers 30b, 30d, 30f, and 30h through the fourth switches 6a to 6d.

The first switches 3a to 3d respectively provide connections between the positive-side DACs 1a to 1d and the differential amplifiers 30a, 30c, 30e, and 30g. The second switches 4a to 4d respectively provide connections between the positive-side DACs 1a to 1d and the differential amplifiers 30b, 30d, 30f, and 30h. The third switches 5a to 5d respectively provide connections between the negative-side DACs 2a to 2d and the differential amplifiers 30a, 30c, 30e, and 30g. The fourth switches 6a to 6d respectively provide connections between the negative-side DACs 2a to 2d and the differential amplifiers 30b, 30d, 30f, and 30h. Also, the first switches 3a to 3d and fourth switches 6a to 6d are fed with a polarity inversion signal POL, and controlled by the polarity inversion signal POL. The second switches 4a to 4d and the third switches 5a to 5d are fed with a signal obtained by inverting the polarity inversion signal POL, which is referred to as the inverted polarity inversion signal POLB, hereinafter, and controlled by the inverted polarity inversion signal POLB.

The bias circuit 28 generates reference voltages used in the differential amplifiers 30a to 30h. The bias circuit 28 is connected to the differential amplifiers 30a to 30h through the bias bus 29. The bias circuit 28 outputs the reference voltages to the differential amplifiers 30a to 30h through the bias bus 29.

The differential amplifiers 30a, 30c, 30e, and 30g receive the gray-level voltages from the positive-side DACs 1a to 1d or the negative-side DACs 2a to 2d to drive the odd-numbered data lines 14a to 14d. The differential amplifiers 30b, 30d, 30f, and 30h receive the gray-level voltages from the positive-side DACs 1a to 1d or the negative-side DACs 2a to 2d to drive the even-numbered data lines 15a to 15d. Also, the differential amplifiers 30a to 30h receive the reference voltages from the bias circuit 28 on reference voltage terminals V1 to V4, which are described later.

The short-circuiting switches 11a to 11d provide connections between the odd-numbered data lines 14a to 14d and the even-numbered data lines 15a to 15d corresponding to the odd-numbered data lines 14a to 14d, respectively. Also, the common node connecting switches 10a to 10d respectively provide connections between the odd-numbered and even-numbered data lines 14a, 14b, 15c, and 15d and the common node 21. The short-circuiting switches 11a to 11d achieve short-circuiting between the odd-numbered data lines 14a to 14d and the even-numbered data lines 15a to 15d, and the common node connecting switches 10a to 10d achieve short-circuiting of the data lines 14a, 14b, 15c, and 15d to the common node 21. When the common node connecting switches 10a to 10d and the short-circuiting switches 11a to 11d are simultaneously turned on, the odd-numbered data lines 14a to 14d and the even-numbered data lines 15a to 15d are all short-circuited. The common node connecting switches 10a to 10d and the short-circuiting switches 11a to 11d are fed with a strobe signal STB, and controlled by the strobe signal STB.

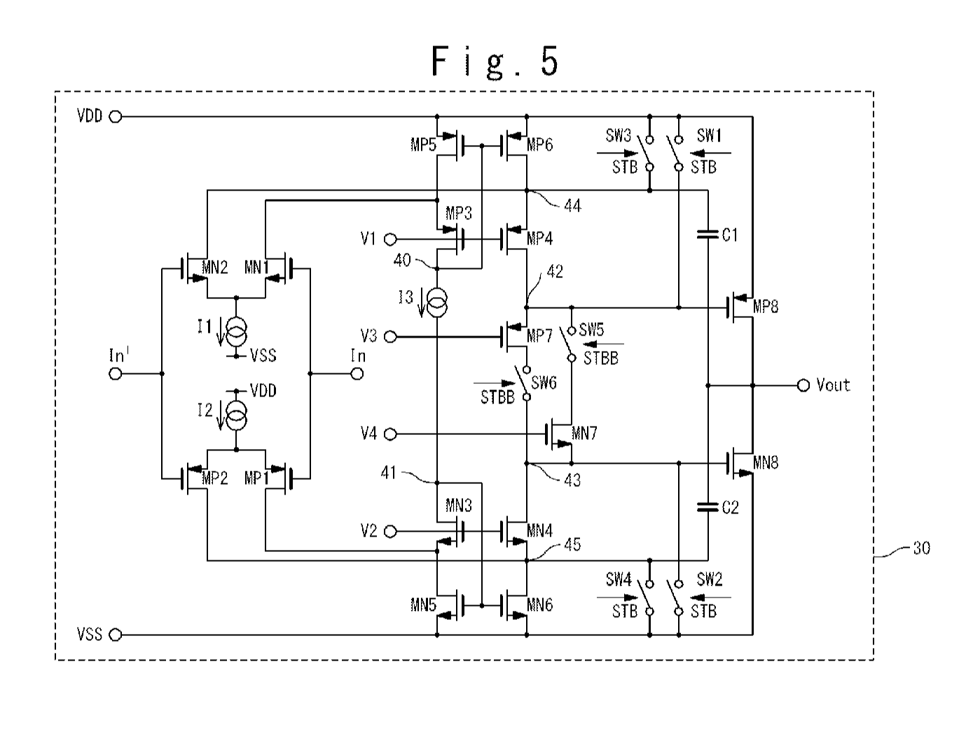

Referring to FIG. 5, a description is then given of an exemplary configuration of the differential amplifiers 30a to 30h in this embodiment, each of which is configured as a voltage follower in FIG. 4. It should be noted that the differential amplifiers 30a to 30h have the same configuration. In the following, the differential amplifiers 30a to 30h are collectively denoted by the differential amplifiers 30. FIG. 5 is a diagram illustrating an exemplary configuration of each differential amplifier 30 in this embodiment.

An input stage circuit of each differential amplifier 30 is provided with first and second differential input stage circuits. The first differential input stage circuit includes a pair of P-type transistors MP1 and MP2 having sources commonly connected to the positive power supply VDD through a current source I2 that supplies a constant current. The second differential input stage circuit includes a pair of N-type transistors MN1 and MN2 having sources commonly connected to the negative power supply VSS through a current source I1 that supplies a constant current.

The gates of the P-type transistor MP1 and N-type transistor MN1 are connected to an input terminal In−. The input terminal In− is connected to an output terminal Vout of the differential amplifier 30. The gates of the P-type transistor MP2 and the N-type transistor MN2 are connected to an input terminal In+. The input terminal In+ is connected to the corresponding switches in the switching section 17.

The drain of the P-type transistor MP1 of the first differential input stage circuit is connected to the drain of an N-type transistor MN5 having a source connected to the negative power supply VSS, and the drain of the P-type transistor MP2 is connected to the drain of an N-type transistor MN6 having a source connected to the negative power supply VSS.

The drain of the N-type transistor MN5 is further connected to the source of an N-type transistor MN3, and the drain of the N-type transistor MN6 is further connected to the source of an N-type transistor MN4.

The gates of the N-type transistors MN3 and MN4 are commonly connected to the reference voltage terminal V2, and fed with a reference voltage from the reference voltage terminal V2. The gates of the N-type transistors MN5 and MN6 are commonly connected to a terminal 41 which is connected to the drain of the N-type transistor MN3. The N-type transistors MN5 and MN6 constitute a current mirror.

The drain of the N-type transistor MN1 of the second differential input stage circuit is connected to the drain of a P-type transistor MP5 having a source connected to the positive power supply VDD. Also, the drain of the N-type transistor MN2 is connected to the drain of a P-type transistor MP6 having a source connected to the positive power supply VDD.

The drain of the P-type transistor MP5 is further connected to the source of a P-type transistor MP3, and the drain of the P-type transistor MP6 is further connected to the source of a P-type transistor MP4.

The gates of the P-type transistors MP3 and MP4 are commonly connected to the reference voltage terminal V1, and fed with a reference voltage from the reference voltage terminal V1. The gates of the P-type transistors MP5 and MP6 are commonly to a terminal 40 which is connected to the drain of the P-type transistor MP3. The P-type transistors MP5 and MP6 constitute a current mirror. Also, a current source I3 is provided as a floating current source between the terminals 40 and 41.

The drain of the P-type transistor MP4 is connected to a terminal 42 and the drain of the N-type transistor MN4 is connected to a terminal 43. Connected between the terminals 42 and 43 is an AB class bias control circuit including: a P-type transistor MP7 having a source connected to the terminal 42; a current cutting switch SW6 connected in series to the drain of the P-type transistor MP7; an N-type transistor MN7 having a source connected to the terminal 43; and a current cutting switch SW5 connected in series to the drain of the N-type transistor MN7. The current cutting switches SW5 and SW6 are controlled by a signal STBB generated by inverting the strobe signal STB.

An output stage of the differential amplifier 30 includes a P-type transistor MP8 having a source connected to the positive power supply VDD and an N-type transistor MN8 having a source connected to the negative power supply VSS, and the output terminal Vout connected to the drains of the P-type and N-type transistors MP8 and MN8. The P-type transistor MP8 and the N-type transistor MN8 are connected in series between the positive and negative power supplies VDD and VSS. The gate of the P-type transistor MP8 is connected to the terminal 42 and the gate of the N-type transistor MN8 is connected to the terminal 43. A short-circuiting switch SW1 is provided between the terminal 42 and the positive power supply VDD to provide short-circuiting of the gate and source of the P-type transistor MP8. Additionally, a short-circuiting switch SW2 is provided between the terminal 43 and the negative power supply VSS to provide short-circuiting between the gate and source of the N-type transistor MN8. The short-circuiting switches SW1 and SW2 are controlled by the strobe signal STB.

The drain of the P-type transistor MP6 is connected to a terminal 44. A phase compensation capacitor C1 is provided between the terminal 44 and the output terminal Vout. The drain of the N-type transistor MN6 is connected to a terminal 45. A phase compensation capacitor C2 is provided between the terminal 45 and the output terminal Vout. A short-circuiting switch SW3 is provided between the terminal 44 and the positive power supply VDD. Additionally, a short-circuiting switch SW4 is provided between the terminal 45 and the negative power supply VSS. The short-circuiting switches SW3 and SW4 are controlled by the strobe signal STB.

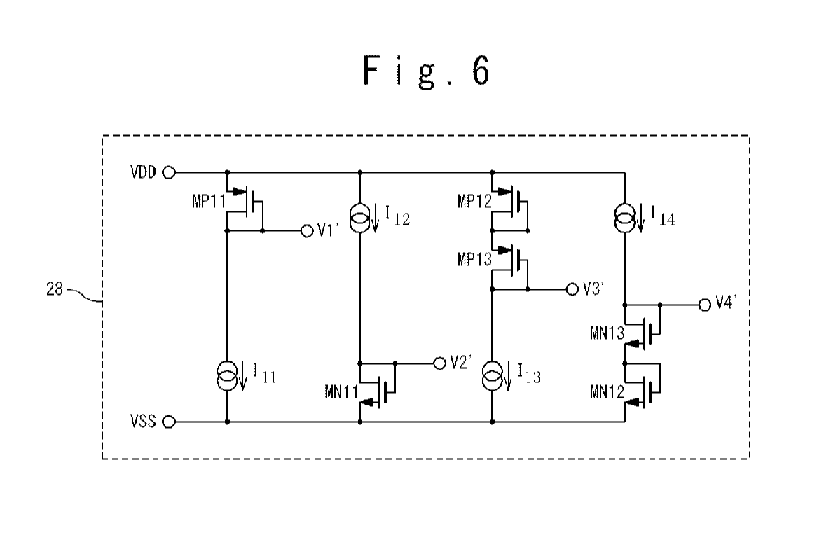

Next, a description is given of an exemplary configuration of the bias circuit 28 in this embodiment, with reference to FIG. 6. FIG. 6 is a diagram illustrating the configuration of the bias circuit 28 of this embodiment.

A diode-connected P-type transistor MP11 is connected in series to a current source I11 between the positive power supply VDD and the negative power supply VSS. The source of the P-type transistor MP11 is connected to the positive power supply VDD, and the drain of the P-type transistor MP11 is connected to the gate of the P-type transistor MP11, the current source I11, and a reference voltage terminal V1′. The P-type transistor MP11 outputs a reference voltage having a voltage level identical to the drain potential thereof to the reference voltage terminal V1′.

A diode-connected N-type transistor MN11 is connected in series to a current source I12, and provided between the positive power supply VDD and the negative power supply VSS. The source of the N-type transistor MN11 is connected to the negative power supply VSS, and the drain of the N-type transistor MN11 is connected to the gate of the N-type transistor MN11, the current source I12, and a reference voltage terminal V2′. The N-type transistor MN11 outputs a reference voltage having a voltage level identical to the drain potential thereof to the reference voltage terminal V2′.

Diode-connected P-type transistors MP12 and MP13 are connected in series to a current source I13 between the positive power supply VDD and the negative power supply VSS. The source of the P-type transistor MP12 is connected to the positive power supply VDD, and the drain of the P-type transistor MP12 is connected to the gate of the P-type transistor MP12 and the source of the P-type transistor MP13. The drain of the P-type transistor MP13 is connected to the gate of the P-type transistor MP13, a current source I13, and a reference voltage terminal V3′. The P-type transistor MP13 outputs a reference voltage having a voltage level identical to the drain potential thereof to the reference voltage terminal V3′.

Diode-connected N-type transistors MN12 and MN13 are connected in series to a current source I14 between the positive power supply VDD and the negative power supply VSS. The source of the N-type transistor MN12 is connected to the negative power supply VSS. The drain of the N-type transistor MN12 is connected to the gate of the N-type transistor MN12 and the source of the N-type transistor MN13. The drain of the N-type transistor MN13 is connected to the gate of the N-type transistor MN13, the current source I14, and a reference voltage terminal V4′. The N-type transistor MN13 outputs a reference voltage having a voltage level identical to the drain potential thereof to the reference voltage terminal V4′.

It should be noted that the reference voltage terminals V1′, V2′, V3′, and V4′ illustrated in FIG. 6 respectively correspond to the reference voltage terminal V1, V2, V3, and V4 of the differential amplifier 30 illustrated in FIG. 5. The reference voltage terminals V1′, V2′, V3′, and V4′ are connected to the reference voltage terminals V1, V2, V3, and V4 within each of the differential amplifiers 30a to 30h through the bias bus 29 illustrated in FIG. 4 to operate the current mirrors therein.

### [Device Operation]

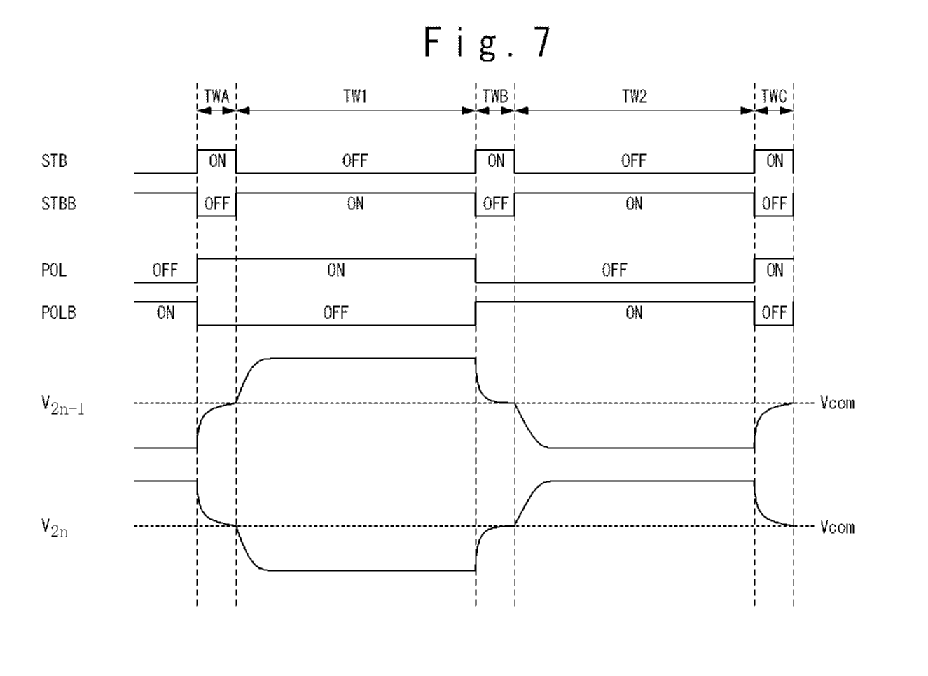

Referring to FIG. 7, a description is next given of an exemplary operation of the display device thus configured in this embodiment. FIG. 7 is a timing chart showing the operation of the display device in this embodiment. In the following, an operation for a case where the data line drive circuit 32 performs the dot inversion driving is described.

In the timing chart of FIG. 7, “STB” denotes the strobe signal that controls the common node connecting switches 10a to 10d and the short-circuiting switches 11a to 11d and “STBB” denotes the inversion signal of the strobe signal. “POL” denotes the polarity inversion signal that controls the first switches 3a to 3d and fourth switches 6a to 6d and “POLB” denotes the inversion signal of the polarity inversion signal, which controls the second switches 4a to 4d and third switches 5a to 5d. The odd-numbered output V₂ₙ₋₁ represents the gray-level voltages (hereinafter, which may be referred to as odd-numbered outputs) outputted to the odd-numbered data lines 14a to 14d. The even-numbered output V₂ₙ represents the gray-level voltages (hereinafter may be referred to as even-numbered outputs) outputted to the even-numbered data lines 15a to 15d. It should be noted that the following description is given with an assumption that the gray-level voltages outputted to the data lines 14a to 14d have the same voltage level and those outputted to the data lines 15a to 15d have the same voltage level.

As shown in FIG. 7, gray-level voltage output periods during which the gray-level voltages are outputted to display an image, and switching periods during which the data lines are neutralized to a voltage level near the common electrode level Vcom are repeated.

The gray-level voltage output periods include a first gray-level voltage output period TW1 and a second gray-level voltage output period TW2. During the gray-level voltage output period TW1, a positive gray-level voltage is supplied to the odd-numbered data lines 14a to 14d, and a negative gray-level voltage is supplied to the even-numbered data lines 15a to 15d. During the gray-level voltage output period TW2, a negative gray-level voltage is supplied to the odd-numbered data lines 14a to 14d, and a positive gray-level voltage is supplied to the even-numbered data lines 15a to 15d. The first gray-level voltage output period TW1 and the second gray-level voltage output period TW2 are alternately provided. Between successive two of the gray-level voltage output periods, the switching periods TWA, TWB and TWC are provided. The switching periods TWA, TWB and TWC is provided every time the polarity inversion signal POL is switched to switch the polarities of the outputted gray-level voltages. The gray-level voltage output periods last during periods when the strobe signal STB is set to the low level, whereas the switching periods last during periods when the strobe signal STB is set to the high level. In the following, the operations in the respective periods are described.

### <Switching Period TWA>

When the polarity inversion signal POL is pulled up to the high level in the switching period TWA, the first switches 3a to 3d and fourth switched 6a to 6d are turned on, and the second switches 4a to 4d and third switches 5a to 5d are turned off. As a result, the positive-side DACs 1a to 1d are connected to the differential amplifiers 30a, 30c, 30e, and 30g, and the negative-side DACs 2a to 2d are connected to the differential amplifiers 30b, 30d, 30f, and 30h.

The strobe signal STB is pulled up to the high level simultaneously with the pull-up of the polarity inversion signal POL. As described above, the period during which the strobe signal STB is set to the high level corresponds to the switching period TWA. When the strobe signal STB is pulled up to the high level, the outputs of the differential amplifiers 30a to 30h are set to the high impedance state, and at the same time, the short-circuiting switches 11a to 11d and common node connecting switches 10a to 10d are turned on. The differential amplifiers 30a to 30h stop driving the data lines 14a to 14d and 15a to 15d as a result of setting the outputs of the differential amplifiers 30a to 30h to the high impedance state. Also, the odd-numbered data lines 14a to 14d and the corresponding even-numbered data lines 15a to 15d are short-circuited by turning on the short-circuiting switches 11a to 11d.

Furthermore, the data lines 14a to 14d and the data lines 15a to 15d are connected to the common node 21 through the common node connecting switches 10a to 10d by turning on the common node connecting switches 10a to 10d. For example, the pair of the data lines 14a and 15a is short-circuited by the short-circuiting switch 11a, and also connected to the common node 21 by the common node connecting switch 10a. By short-circuiting the data lines 14a to 14d and the data lines 15a to 15d through the common node 21 in this manner, the charges accumulated on the data lines 14a to 14d and 15a to 15d are neutralized, and the voltage levels of the respective data lines 14a to 14d and 15a to 15d are brought to a voltage level close to the common electrode level Vcom.

### <First Gray-Level Voltage Output Period Tw1>

The strobe signal STB is then pulled down to the low level. During the first gray-level voltage output period TW1, the polarity inversion signal POL is set to the high level and the strobe signal STB is set to the low level. When the strobe signal STB is set to the low level, the common node switches 10a to 10d and the short-circuiting switches 11a to 11d are turned off, and gray-level voltages of desired polarities are outputted to the data lines 14a to 14d and 15a to 15d from the differential amplifiers 30a to 30h. For example, the data line 14a is supplied with a gray-level voltage outputted from the differential amplifier 30a in response to a positive-side signal, and the data line 15a is supplied with a gray-level voltage outputted from the differential amplifier 30b in response to a negative-side signal.

### <Switching Period TWB>

When the polarity inversion signal POL is then pulled down to the low level, the first switches 3a to 3d and fourth switches 6a to 6d are turned off, and the second switches 4a to 4d and third switches 5a to 5d are turned on. As a result, the positive-side DACs 1a to 1d are connected to the differential amplifiers 30b, 30d, 30f, and 30h, and the negative-side DACs 2a to 2d are connected to the differential amplifiers 30a, 30c, 30e, and 30g.

The strobe signal STB is pulled up to the high level simultaneously with the pull-down of the polarity inversion signal POL. During the switching period TWB, the strobe signal STB is set to the high level. When the strobe signal STB is set to the high level, the outputs of the differential amplifiers 30a to 30h are set to the high impedance state, and at the same time, the short-circuiting switches 11a to 11d and the common node connecting switches 10a to 10d are turned on. The differential amplifiers 30a to 30h stop driving the data lines 14a to 14d and 15a to 15d by setting the outputs of the differential amplifiers 30a to 30h to the high impedance state. Also, by turning on the short-circuiting switches 11a to 11d, the odd-numbered data lines 14a to 14d and the corresponding even-numbered data lines 15a to 15d are respectively short-circuited.

Further, the data lines 14a to 14d and the data lines 15a to 15d are connected to the common node 21 through the common node connecting switches 10a to 10d by turning on the common node connecting switches 10a to 10d. By short-circuiting the data lines 14a to 14d and the data lines 15a to 15d through the common node 21 in this manner, charges accumulated on the data lines 14a to 14d and 15a to 15d are neutralized, and the voltage levels of the data lines 14a to 14d and 15a to 15d are set to a voltage level close to the common electrode level Vcom.

### <Second Gray-Level Voltage Output Period TW2>

The strobe signal STB is then pulled down to the low level at the beginning of the second gray-level voltage output period TW2. During the second gray-level voltage output period TW2, the polarity inversion signal POL is set to the low level and the strobe signal STB is also set to the low level. When the strobe signal STB is pulled down to the low level, the common node switches 10a to 10d and short-circuiting switches 11a to 11d are turned off, and the gray-level voltages of opposite polarities are outputted from the differential amplifiers 30a to 30h to the data lines 14a to 14d and 15a to 15d. For example, the data line 14a is supplied with a gray-level voltage outputted from the differential amplifier 30b in response to a negative-side signal, and the data line 15a is supplied with a gray-level voltage outputted from the differential amplifier 30a in response to a positive-side signal.

### <Switching Period TWC>

The strobe signal STB and the polarity inversion signal POL are then simultaneously pulled up to the high level at the beginning of the switching period TWC. The operation during the switching period TWC is same as that during the switching period TWA, and therefore no description thereof is given. As described, the display device repeats the above-described switching period TWA, first gray-level voltage output period TW1, the switching period TWB, and second gray-level voltage output period TW2 to supply the gray-level voltages to the data lines 14a to 14d and 15a to 15d.

Referring to FIGS. 5 and 7, a description is then given of an exemplary operation of the differential amplifiers 30a to 30h in this embodiment is described. It should be note that the differential amplifiers 30a to 30h perform the same operation similarly to the description using FIG. 5. In the following description, the differential amplifiers 30a to 30h are collectively denoted by the differential amplifiers 30. Also, it is assumed that the bias circuit 28 supplies constant biases to the reference voltage terminals V1, V2, V3, and V4 of the respective differential amplifiers 30 through the bias bus 29.

When the strobe signal STB is set to the high level at the beginning of the switching period TWA, the short-circuiting switches SW1 and SW2 are turned on. As a result, the gate and source of the P-type transistor MP8 are short-circuited and the gate and source of the N-type transistor MN8 are short-circuited. This results in that the P-type and N-type transistors MP8 and MN8 are both turned off, and the output terminal Vout is set to the high impedance state. In addition, the short-circuiting switches SW3 and SW4 are turned on in response to the strobe signal STB being set to the high level. As a result, the terminal 44 of the phase compensation capacitor C1 is short-circuited to the positive power supply VDD, and the terminal 45 of the phase compensation capacitor C2 is short-circuited to the negative power supply VSS. During the switching period TWA during which the strobe signal STB is set to the high level, as described above, the voltage level of the output terminal Vout is set close to the common electrode level Vcom, and therefore the phase compensation capacitors C1 and C2 are also charged/discharged to near the common electrode level Vcom by the charges of the liquid crystal panel 22. This allows reducing the power and time duration required to charge/discharge the phase compensation capacitors C1 and C2 after the switching of the polarities of the output gray-level voltages.

Also, the current cutting switches SW5 and SW6 are turned off in response to the inversion signal STBB of the strobe signal STB during the switching period TWA during which the strobe signal STB is set to the high level. This effectively allows avoiding an abnormal current flowing from the positive power supply VDD to the negative power supply VSS through the short-circuiting switch SW1, the P-type transistor MP7, the N-type transistor MN7 and the short-circuiting switch SW2, and avoiding an abnormal current flowing from the positive power supply VDD to the negative power supply VSS through the short-circuiting switch SW3, the P-type transistor MP4, the P-type transistor MP7, the N-type transistors MN7, N-type transistor MN4, and the short-circuiting switch SW4.

When the strobe signal STB is then pulled down to the low level at the beginning of the first gray-level voltage output period TW1, the short-circuiting switches SW1, SW2, SW3, and SW4 are turned off, and the current cutting switches SW5 and SW6 are turned on. As a result, the differential amplifier 30 is restored to the normal operation. At this time, the phase compensation capacitors C1 and C2 have been charged/discharged to a voltage level close to the common electrode level Vcom during the switching period TWA, and the data line connected to the output terminal Vout is also brought to the voltage level close to the common electrode level Vcom as described in the above, so that the voltage level of the output terminal Vout is driven from the common electrode level Vcom to the same level as that of the input terminal In+.

It should be note that, although only the operation during the switching period TWA is described, the person skilled in the art would appreciate that the differential amplifiers 30a to 30h also operate in the same way during other switching periods, including the switching periods TWB and TWC.

It should be emphasized that, the differential amplifiers 30a to 30h are each provided with the short-circuiting switches SW1, SW2, SW3, and SW4 and the current cutting switches SW5 and SW6 in the display device of this embodiment. The short-circuiting switch SW1 short-circuits the gate and source of the output stage P-type transistor MP8 and the short-circuiting switch SW2 short-circuits the gate and source of the N-type transistor MN8. The short-circuiting switch SW3 is connected in series between the terminal 44 of the phase compensation capacitor C1 and the positive power supply VDD, and the short-circuiting switch SW4 is connected in series between the terminal 45 of the phase compensation capacitor C2 and the negative power supply VSS. The current cutting switch SW5 is connected in series between the drain of the N-type transistor MN7 and the terminal 42. The current cutting switch SW6 is connected in series between the drain of the P-type transistor MP7 and the terminal 43.

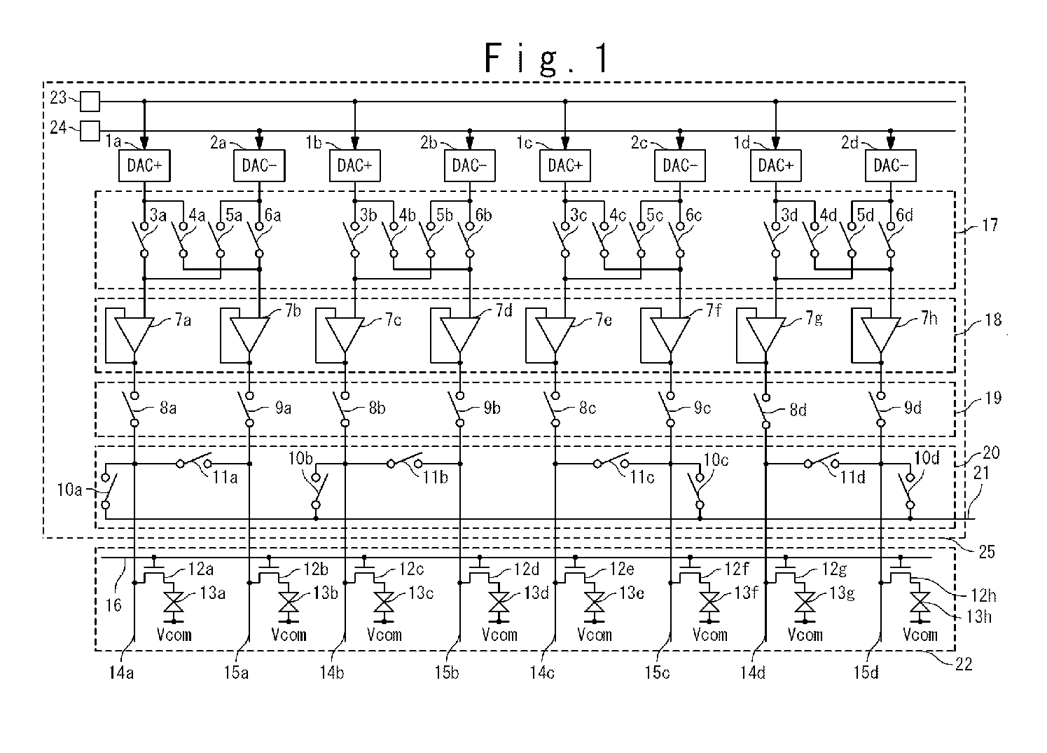

Such a configuration allows short-circuiting the gate and source of the P-type transistor MP8 and the gate and source of the N-type transistor MN8 by the short-circuiting switches SW1 and SW2 during the switching periods TWA, TWB and TWC, during which the strobe signal STB is set to the high level. As a result, the P-type transistor MP8 and the N-type transistor MN8 are turned off to thereby place the output terminal Vout into the high impedance state. This effectively eliminates the need for providing output switches that have conventionally been provided to disconnect the differential amplifiers 30a to 30h from the data lines 14a to 14d and 15a to 15d (the output switches 8a to 8d and 9a to 9d shown in FIG. 1), reducing the output impedances between the output terminals Vout of the differential amplifiers 30a to 30h and the data lines 14a to 14d and 15a to 15d during the gray-level voltage output period TW1 or TW2, so that the current output characteristics are improved. As a result, the speed of the data writing from the differential amplifiers 30a to 30h onto the data lines 14a to 14d and 15a to 15d can be enhanced to avoid the delay of the data writing, which prevents the image quality of the display device from being deteriorated even in a case where the duration of each horizontal synchronization period is decreased.

Also, the configuration in which the output stages of each of the differential amplifiers 30a to 30h can be set to the high impedance state effectively eliminates the need for providing output switches that has conventionally been provided, and thereby reduces the heat generation amount due to power consumption of the currents through the output switches, reducing the total heat generation amount of the LSI used as the source driver of the display device. Further, the chip area and cost of the LSI used as the source driver can be decreased as a whole by increasing the number of small-sized transistors used as switches for flowing small currents within the differential amplifiers 30a to 30g, and eliminating large-sized transistors used as switches for flowing large output currents.

### Second Embodiment

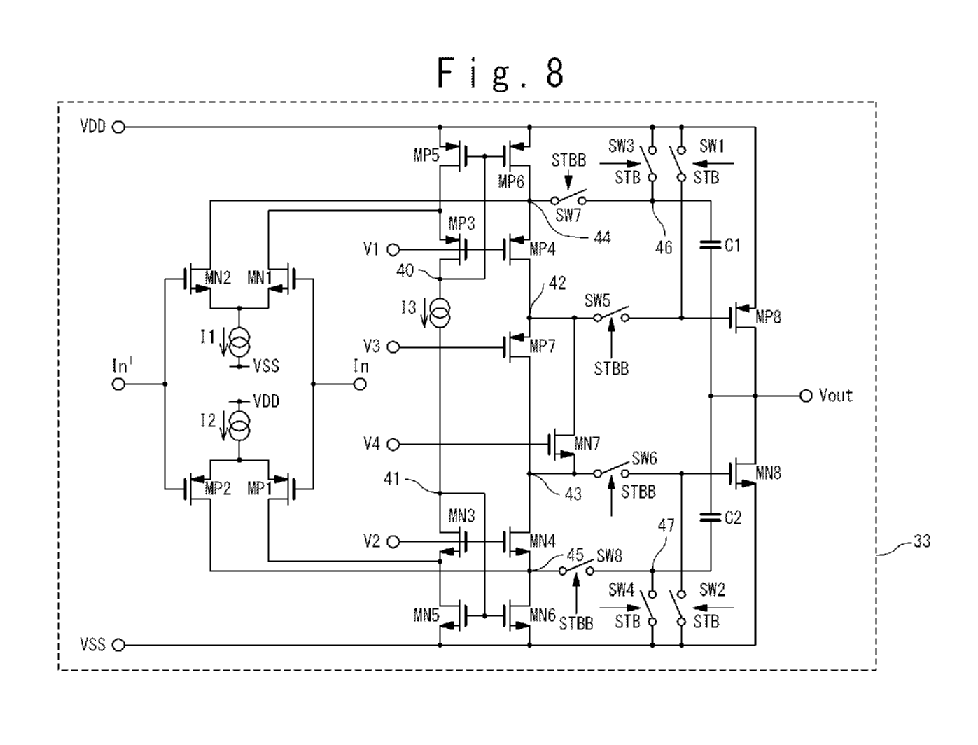

Next, a description is given of a display device in a second embodiment of the present invention. The display device of this embodiment is different from that of the first embodiment in the configuration of the differential amplifiers 30a to 30h. The differences are focused on in the following description, and no description is given of the same points as those in the first embodiment. In the following description, the differential amplifiers 30a to 30h, which have the same configuration, are collectively referred to as the differential amplifiers 33. FIG. 8 is a diagram illustrating an exemplary configuration of the differential amplifier 33 in this embodiment.

The differential amplifier 33 of this embodiment is different from that of the first embodiment in that the current cutting switches SW5 and SW6 are provided at different positions and current cutting switches SW7 and SW8 are additionally provided. In the differential amplifier 33 of this embodiment, the P-type transistor MP7 and the N-type transistor MN7 are connected in parallel to each other to configure an AB class bias control circuit between terminals 42 and 43.

Referring to FIG. 8, the current cutting switch SW5 is provided between the terminal 42 and the gate of the P-type transistor MP8 in this embodiment. Also, the current cutting switch SW6 is provided between the terminal 43 and the gate of the N-type transistor MN8 in this embodiment. Further, the differential amplifier 33 of this embodiment further includes the current cutting switches SW7 and SW8. The current cutting switch SW7 is provided between the terminals 44 and 46 and the current cutting switch SW8 is provided between terminals 45 and 47.

The current cutting switches SW5 to SW8 are controlled by the inversion signal STBB of the strobe signal STB. During a period when the strobe signal STB is set to the high level, the short-circuiting switches SW1 to SW4 are turned on in the same manner as the first embodiment, and the current cutting switches SW5 to SW8 are turned off. This effectively avoids an abnormal current flowing from the positive power supply VDD to the negative power supply VSS through the short-circuiting switch SW1, the P-type transistor MP7, the N-type transistor MN7 and the short-circuiting switch SW2, and an abnormal current flowing from the positive power supply VDD to the negative power supply VSS through the short-circuiting switch SW3, the P-type transistor MP4, the P-type transistor MP7, the N-type transistors MN7, the N-type transistor MN4 and the short-circuiting switch SW4.

It should be noted that configurations of the display device of the second embodiment other than those described above are same as those of the first embodiment. As described, the differential amplifiers 30a to 30h of this embodiment are provided with the current cutting switches SW5, SW6, SW7, and SW8 at the above described positions, respectively. In addition, no current cutting switches are connected in series to respective drains of the P-type and N-type transistors MP7 and MN7. Such a configuration allows constantly flowing a current having the same current level as that of the current through the current source I3 through the P-type and N-type transistors MP7 and MN7 during the switching periods. As a result, the current path from the positive power supply VDD to the negative power supply VSS through the P-type transistors MP6, MP4, and MP7 and N-type transistors MN7, MN4, and MN6 is brought into a conduction state. This eliminates the need for charging the drain and source capacitances of the respective transistors connected to the terminals 42, 43, 44, and 45 at the time when the strobe signal STB is set to the low level to restore the differential amplifiers 30a to 30h to the normal operation, allowing operating the differential amplifiers 30a to 30h at a higher speed.

### Third Embodiment

Next, a description is given of a display device of a third embodiment of the present invention.

### [Device Configuration]

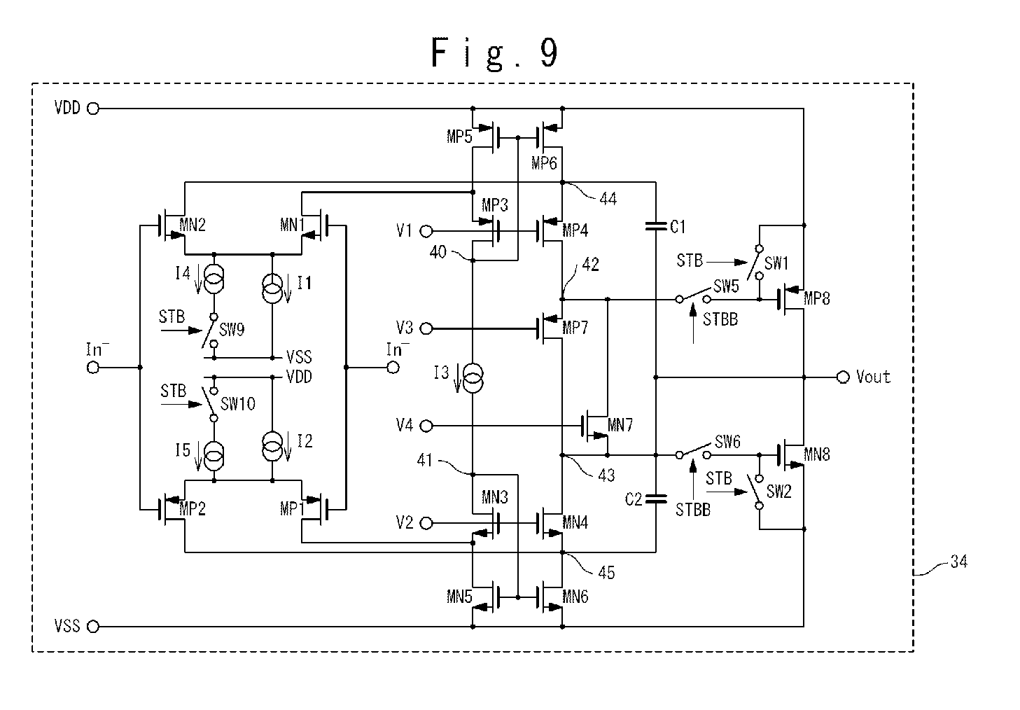

First, an exemplary configuration of the display device of this embodiment is described. The display device in this embodiment is different from that in the second embodiment in the configuration of the differential amplifiers. Specifically, the differential amplifiers 34 of this embodiment is different from those of the second embodiment in that the short-circuiting switches SW3 and SW4 and the current cutting switches SW7 and SW8 are not provided and short-circuiting switches SW9 and SW10 are provided instead. The differences are focused on in the following description, and no description is given of the same points as those in the second embodiment. In the following description, the differential amplifiers 30a to 30h, which have the same configuration, are collectively referred to as the differential amplifiers 34. FIG. 9 is a diagram illustrating the configuration of the differential amplifiers 34 in this embodiment.

An input stage circuit of the differential amplifier 34 is provided with a first differential input stage circuit and a second differential input stage circuit. The first differential input stage circuit includes P-type transistors MP1 and MP2 having sources commonly connected to first terminals of current sources I2 and I5 that respectively supply constant currents. A second terminal of the current source I2 is connected to the positive power supply VDD. A second terminal of the current source I5 is connected to the positive power supply VDD through the short-circuiting switch SW10. Also, the second differential input stage circuit includes N-type transistors MN1 and MN2 having sources commonly connected to first terminals of current sources I1 and 14 that respectively supply constant currents. A second terminal of the current source I1 is connected to the negative power supply VSS. A second terminal of the current source I4 is connected to the negative power supply VDD through the short-circuiting switch SW9. In addition, the short-circuiting switches SW9 and SW10 are both controlled by the strobe signal STB. The current sources I4 and I5 and the short-circuiting switches SW9 and SW10 provide control of the bias currents flowing through the input stage circuits to control the slew rate at the output terminal Vout of the differential amplifier 34.

It should be note that configurations other than those described above are the same as those in the second embodiment.

### [Device Operation]

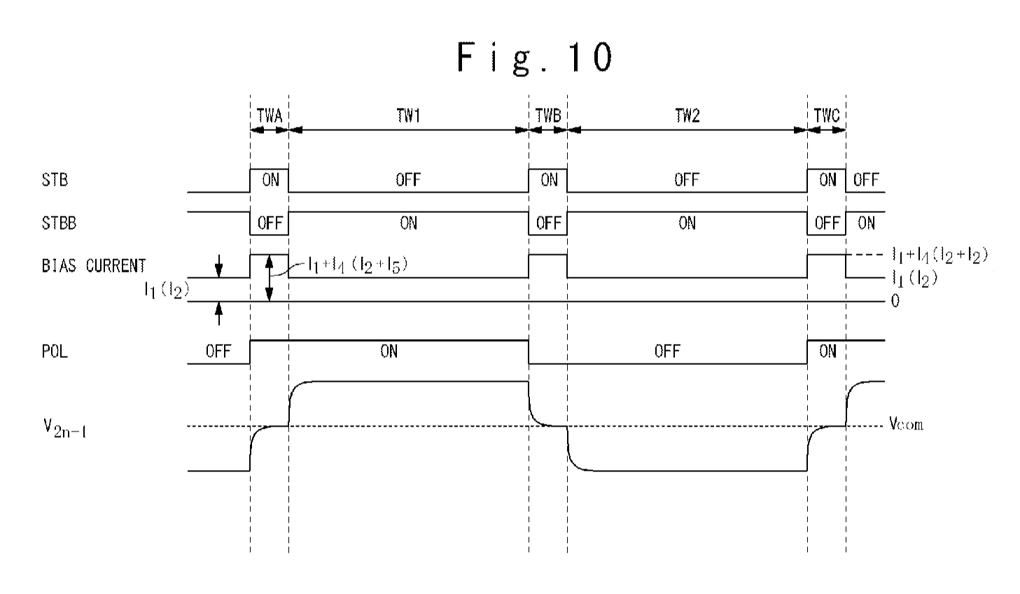

Next, a description is given of an exemplary operation of the display device in this embodiment. The display device in this embodiment is different in the operation of the differential amplifiers from that in the second embodiment. FIG. 10 is a timing chart of the display device in this embodiment. In the following, a description is given for a case where the data line drive circuit 32 performs a dot inversion driving.

In the timing chart of FIG. 10, “STB” denotes the strobe signal that controls the common node connecting switches 10a to 10d and the short-circuiting switches 11a to 11d and “STBB” denotes the inversion signal of the strobe signal. “POL” denotes the polarity inversion signal that controls the first switches 3a to 3d and fourth switches 6a to 6d. The odd-numbered output V₂ₙ₋₁ represents the gray-level voltages (hereinafter, which may be referred to as odd-numbered outputs) outputted to the odd-numbered data lines 14a to 14d. The even-numbered output V₂ₙ represents the gray-level voltages (hereinafter may be referred to as even-numbered outputs) outputted to the even-numbered data lines 15a to 15d. It should be noted that the following description is given with an assumption that the gray-level voltages outputted to the data lines 14a to 14d have the same voltage level and those outputted to the data lines 15a to 15d have the same voltage level.

When the strobe signal STB is pulled up to the high level at the beginning of the switching period TWA, the short-circuiting switches SW1 and SW2 are turned on so that the source and gate the P-type transistor MP8 are short-circuited and the source and gate the N-type transistor MN8 are short-circuited. As a result, the P-type transistor MP8 and the N-type transistor MN8 are turned off, and consequently the output terminal Vout is set to the high impedance state. The short-circuiting switches SW9 and SW10 are also simultaneously turned on when the strobe signal STB is set to the high level. As a result, the currents flow through the current sources I4 and I5, and thereby the bias currents through the input stage circuits are increased by the current levels of the current sources I4 and I5. That is, as illustrated in FIG. 10, the bias currents flowing through the respective input stage circuits at this time are (I2+I5) for the first differential input stage circuit and (I1+I4) for the second differential input stage circuit, respectively.

The slew rate SR at the output terminal Vout of the differential amplifier 34 is determined as SR=I/C, given that the bias currents within the input stage circuit and the capacitance of the phase compensation capacitors are respectively denoted by I and C. Thus, the slew rate is increased by the increase in bias current of the input stage circuit. This implies that desired charges can be instantaneously charged/discharged to/from phase compensation capacitors C1 and C2 by appropriately designing the bias currents I4 and I5 flowing through the current sources I4 and I5. That is, since the voltage level of the output terminal Vout is neutralized to a voltage level close to the common electrode level Vcom during a period during which the strobe signal STB is set to the high level, the phase compensation capacitors C1 and C2 are also charged/discharged to a voltage close to the common electrode level Vcom by the charges of the liquid crystal panel 22.

The pull-up of the strobe signal STB to the high level also results in simultaneously turning off the current cutting switches SW5 and SW6. This effectively avoids an abnormal current flowing from the positive power supply VDD to the negative power supply VSS through the short-circuiting switch SW1, the P-type transistor MP7, the N-type transistor MN7 and the short-circuiting switch SW2.

When the strobe signal STB is then set to the low level at the beginning of the first gray-level voltage output period TW1, the short-circuiting switches SW1, SW2, SW9, and SW10 are turned off, and the current cutting switches SW5 and SW6 are turned on. As a result, the differential amplifier 35 is restored to normal operation. That is, the bias currents flowing through the input stage circuits are reduced down to the bias currents I2 and I1 in the first and second differential input stage circuits, respectively. At this time, the phase compensation capacitors C1 and C2 have been charged/discharged to a voltage level close to the common electrode level Vcom during the switching period TWA, and therefore the voltage level of the output terminal Vout is driven from the common electrode level Vcom to the same voltage level as that of the input terminal In+. It should be noted that, although only the switching period TWA and the first gray-level voltage output period are described above, the person skilled in the art would appreciate that the differential amplifier 35 also operates in the same way during the switching periods TWB and TWC and other switching periods.

It should be note that configurations other than those described above are the same as those in the second embodiment. As thus described, the display device of the present invention allows configuring the differential amplifier with a smaller number of switches, while keeping the same effect as that in the second embodiment.

### Fourth Embodiment

Next, a description is given of a display device of a fourth embodiment of the present invention.

### [Device Configuration]

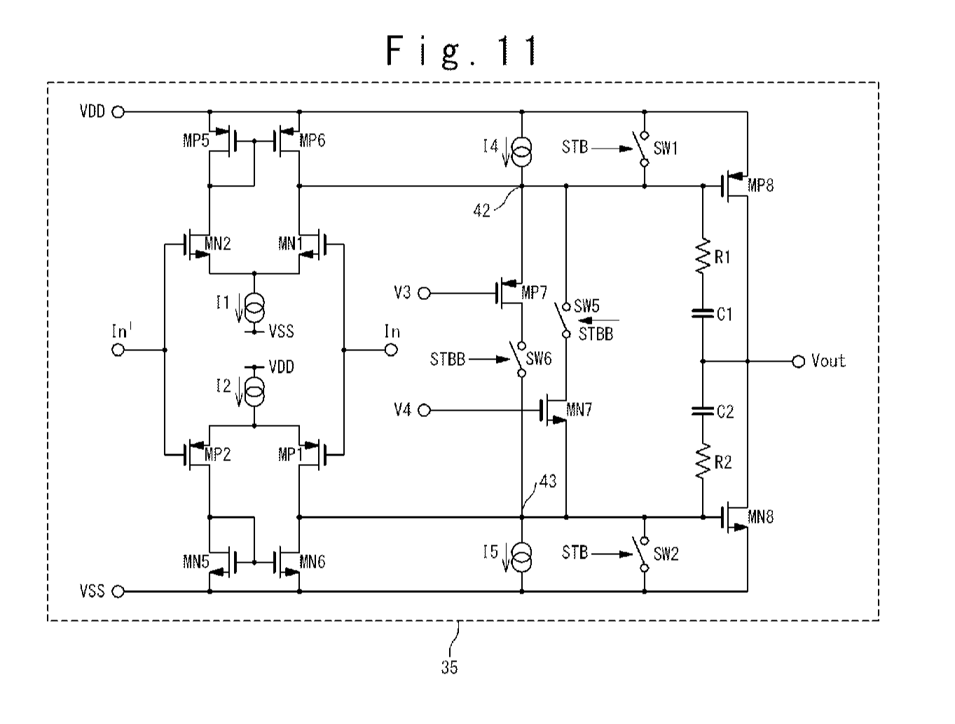

First, a configuration of the display device in this embodiment is described. The display device of this embodiment is different from that of the first embodiment in the configuration of the differential amplifiers. The differences are focused on in the following description, and no description is given of the same points as those in the first embodiment. In the following description, the differential amplifiers 30a to 30h, which have the same configuration, are collectively referred to as the differential amplifiers 35. FIG. 11 is a diagram illustrating an exemplary configuration of the differential amplifier 35 in this embodiment.

An input stage circuit of the differential amplifier 35 in this embodiment is provided with a first differential input stage circuit and a second differential input stage circuit. The first differential input stage circuit includes a pair of P-type transistors MP1 and MP2 having sources commonly connected to the positive power supply VDD through a current source I2 that supplies a constant current. The second differential input stage circuit includes a pair of N-type transistors MN1 and MN2 having sources commonly connected to the negative power supply VSS through a current source I1 that supplies a constant current.

The gates of the P-type and N-type transistors MP1 and MN1 are connected to an input terminal In−, and the gates of the P-type and N-type transistors MP2 and MN2 are connected to an input terminal In+.

The source of an N-type transistor MN5 is connected to the negative power supply VSS. The source of an N-type transistor MN6 is connected to the negative power supply VSS. The drain of the N-type transistor MN5 is connected to the drain of the P-type transistor MP2. The drain of the N-type transistor MN6 is connected to the drain of the P-type transistor MP1. The gate of the N-type transistor MN5 is connected to the gate of the N-type transistor MN6, and further connected to the drain of the N-type transistor MN5 to form a diode connection. The N-type transistors MN5 and MN6 constitute a current mirror as an active load of the first differential input stage circuit.

The source of a P-type transistor MP5 is connected to the positive power supply VDD. The source of a P-type transistor MP6 is connected to the positive power supply VDD. The drain of the P-type transistor MP5 is connected to the drain of the N-type transistor MN2. The drain of the P-type transistor MP6 is connected to the drain of the N-type transistor MN1. The gate of the P-type transistor MP5 is connected to the gate of the P-type transistor MP6, and further connected to the drain of the P-type transistor MP5 to form a diode connection. The P-type transistors MP5 and MP6 constitute a current mirror as an active load of the second differential input stage circuit.

Provided between the drain terminal 42 of the P-type transistor MP6 and the drain terminal 43 of the N-type transistor MN6 is an AB class bias control circuit including: a P-type transistor MP7 having a source connected to the terminal 42, a current cutting switch SW6 connected in series to the drain of the P-type transistor MP7, an N-type transistor MN7 having a source connected to the terminal 43 and a current cutting switch SW5 connected in series to the drain of the N-type transistor MN7. The current cutting switches SW5 and SW6 are controlled by the inversion signal STBB of the strobe signal STB.

A current source I4, which typically includes a current mirror, is provided between the terminal 42 and the positive power supply VDD, and a current source I5, which typically includes a current mirror, is provided between the terminal 43 and the negative power supply VSS.

An output stage of the differential amplifier 35 is configured so that a P-type transistor MP8 having a source connected to the positive power supply VDD and an N-type transistor MN8 having a source connected to the negative power supply VSS are provided in series between the positive and negative power supplies VDD and VSS, and the output terminal Vout is connected to the drains of the P-type and N-type transistors MP8 and MN8. The gate of the P-type transistor MP8 is connected to the terminal 42, and the gate of the N-type transistor MN8 is connected to the terminal 43. A short-circuiting switch SW1 is provided between the terminal 42 and the positive power supply VDD, and a short-circuiting switch SW2 is provided between the terminal 43 and the negative power supply VSS. The short-circuiting switches SW1 and SW2 are controlled by the strobe signal STB.

Between the terminal 42 and the output terminal Vout, a zero point canceling compensation resistor R1 and a phase compensation capacitor C1 are provided in series; the zero point canceling compensation resistor R1 is used to cancel the zero point of the phase delay of the differential amplifier 35. Also, a zero point canceling compensation resistor R2 and a phase compensation capacitor C2 are provided in series between the terminal 43 and the output terminal Vout; the zero point canceling compensation resistor R2 is also used to cancel the zero point of phase delay of the differential amplifier 35.

### [Device Operation]

Next, a description is given of an exemplary operation of the display device in this embodiment, with reference to FIG. 7.

When the strobe signal STB is pulled up to the high level at the beginning of the switching period TWA, the short-circuiting switches SW1 and SW2 are turned on. As a result, the gate and source of the P-type transistor MP8 are short-circuited and the gate and source of the N-type transistor MN8 are short-circuited. This results in that the P-type transistor MP8 and the N-type transistor MN8 are turned off to set the output terminal Vout to the high impedance state.

The turn-on of the short-circuiting switch SW1 results in short-circuiting the terminal 42 of the phase compensation capacitor C1 to the positive power supply VDD. Further, the turn-on of the short-circuiting switch SW2 results in short-circuiting the terminal 43 of the phase compensation capacitor C2 to the negative power supply VSS. During the period during which the strobe signal STB is set to the high level, the voltage level of the output terminal Vout is neutralized to a voltage level close to the common electrode level Vcom, and therefore the phase compensation capacitors C1 and C2 are also charged/discharged to a voltage level close to the common electrode level Vcom by the charges of the liquid crystal panel 22.

Also the current cutting switches SW5 and SW6 are turned off when the strobe signal STB is set to the high level. This effectively avoids an abnormal current flowing from the positive power supply VDD to the negative power supply VSS through the short-circuiting switch SW1, the P-type transistor MP7, the N-type transistor MN7 and the short-circuiting switch SW2.

When the strobe signal is then set to the low level at the beginning of the first gray-level voltage output period TW1, the short-circuiting switches SW1 and SW2 are turned off, and the current cutting switches SW5 and SW6 are turned on. As a result, the differential amplifier 35 is restored to the normal operation. At this time, the phase compensation capacitors C1 and C2 have been charged/discharged to a voltage level close to the common electrode level Vcom during the switching period TWA, and therefore the voltage level of the output terminal Vout is driven from the common electrode level Vcom to the same voltage level as that of the input terminal In+. It should be noted that, although only the switching period TWA and the first gray-level voltage output period are described in the above-description, the differential amplifier 35 operates in the same way during the switching periods TWB and TWC and the other switching periods and other gray-level voltage output periods.

As thus described, according to the display device of the present invention, the differential amplifier can be configured with a smaller number of transistors, while keeping the same effect as that in the first embodiment.

### Fifth Embodiment

Next, a description is given of a display device of a fifth embodiment of the present invention.

### [Description of Configuration]

First, an exemplary configuration of the display device in this embodiment is described. The display device of this embodiment is different from that of the fourth embodiment in the configuration of the differential amplifiers. Specifically, the differential amplifiers of this embodiment, which will be denoted by the numeral 36, are different from those in the fourth embodiment in the positions where current cutting switches SW5 and SW6 are provided. In the following, the different aspects are focused on, and a detailed description of the same aspects as those in the fourth embodiment is not given.

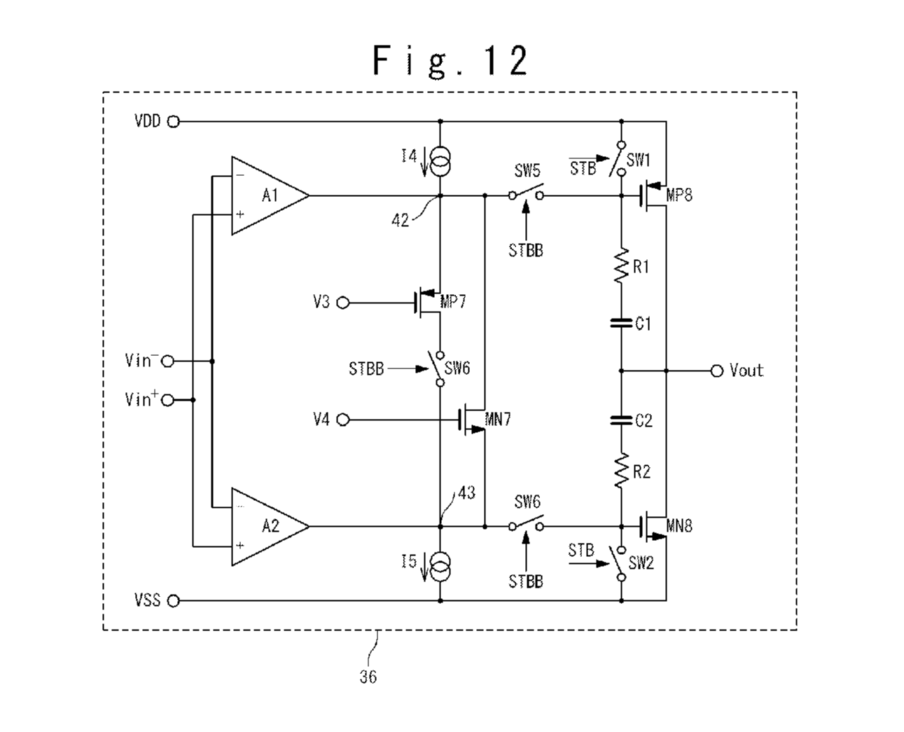

FIG. 12 is a diagram illustrating an exemplary configuration of the differential amplifier 36 of this embodiment. It should be noted that, in FIG. 12, the first differential input stage circuit and the second differential input stage circuit in the fourth embodiment are denoted by “A1” and “A2”, respectively.

In the differential amplifier 36 of this embodiment, the current cutting switch SW5 is provided between the drain of the N-type transistor MN7 and the gate of the P-type transistor MP8. Also, the current cutting switch SW6 is provided between the source of the N-type transistor MN7 and the gate of the N-type transistor MN8. The current cutting switches SW5 and SW6 are controlled by the inversion signal STBB of the strobe signal STB. The configurations other than those described above are the same as those in the fourth embodiment.

### [Description of Operation]

Next, an exemplary operation of the display device in this embodiment is described with reference to FIG. 7.

When the strobe signal STB is pulled up to the high level at the beginning of the switching period TWA as shown in FIG. 7, the short-circuiting switches SW1 and SW2 are turned on. As a result, the gate and source of the P-type transistor MP8 are short-circuited and the gate and source of the N-type transistor MN8 are-short circuited. This results in that the P-type transistor MP8 and the N-type transistor MN8 are turned off to set the output terminal Vout to the high impedance state. At this time, the current cutting switches SW5 and SW6 are turned off, and this effectively avoids an abnormal current flowing from a positive power supply VDD to the negative power supply VSS through the short-circuiting switch SW1, the P-type transistor MP, the N-type transistor MN7, and the short-circuiting switch SW2.

When the strobe signal STB is then set to the low level at the beginning of the first gray-level voltage output period TW1, the short-circuiting switches SW1 and SW2 are turned off, and the current cutting switches SW5 and SW6 are turned on. As a result, the differential amplifier 36 is restored to the normal operation. At this time, the phase compensation capacitors C1 and C2 have been charged/discharged to a voltage level close to the common electrode level Vcom during the switching period TWA, and therefore the voltage level of the output terminal Vout is driven from the common electrode level Vcom to the same voltage level as that of the input terminal In+. It should be noted that, although only the switching period TWA and the first gray-level voltage output period are described in the above, the differential amplifier 35 operates in the same way during the switching periods TWB and TWC, other switching periods, and other.

The operation other than that described above is the same as that in the first embodiment. In the fourth embodiment, the current cutting switches SW6 and SW5 are provided on drain connecting paths of the respective transistors in order to block the abnormal currents flowing through the P-type and N-type transistors MP7 and MN7 due to the bias voltages V3 and V4, whereas the current cutting switches SW5 and SW6 are provided in this embodiment on the short-circuiting paths including the short-circuiting switches SW1 and SW1 which provide short-circuiting to the positive and negative power supplies VDD and VSS, in order to block the same abnormal currents. As a result the same effect as that in the fourth embodiment can be also obtained with the different configuration in this embodiment.

It is apparent that the present invention is not limited to the above embodiments, but may be modified and changed without departing from the scope of the invention.

What is claimed is:

1. A display device, comprising:
a plurality of differential amplifiers associated with a plurality of data lines within a display panel, said plurality of differential amplifiers respectively receiving gray-level voltages which are switched between positive and negative polarities with respect to a reference voltage level and outputting said received gray-level voltages to associated ones of said plurality of data lines; and
an output short-circuiting section providing short-circuiting among said plurality of data lines during a switching period in which polarities of said gray-level voltages received by said plurality of differential amplifiers are switched,
wherein each of said plurality of differential amplifiers includes:
an input circuit including a first differential input stage circuit comprising a first transistor pair and a second differential input stage circuit comprising a second transistor pair, said first and second transistor pairs being complementary;
an adder circuit including a first current mirror circuit provided between said first differential input stage circuit and a positive power supply and a second current mirror circuit provided between said second differential input stage circuit and a negative power supply;
an output stage circuit including a first transistor having a source connected to said positive power supply, a second transistor having a source connected to said negative power supply, an output terminal connected to drains of said first and second transistors, a first phase compensation capacitor provided between said first current mirror circuit and said output terminal, and a second phase compensation capacitor provided between said second current mirror circuit and said output terminal; and
a bias control circuit provided between said adder circuit and said output stage circuit to achieve bias control of gates of said first and second transistors,
wherein, during said switching period, said output stage circuit provides short-circuiting between the gate and source of each of said first and second transistors, and charges or discharges said first and second phase compensation capacitors to a certain voltage level, and
wherein said bias control circuit cuts off a current path between the gates of said first and second transistors during said switching period.

2. The display device according to claim 1, wherein said output stage circuit further includes:
a first switch connected between the gate and source of said first transistor to provide short-circuiting between the gate and source of said first transistor during said switching period;
a second switch connected between the gate and source of said second transistor to provide short-circuiting between the gate and source of said second transistor during said switching period;
a third switch connected between said positive power supply and a first connecting node of said first phase compensation capacitor and said first current mirror circuit to provide short-circuiting between said positive power supply and said first connecting node; and
a fourth switch connected between said negative power supply and a second connecting node of said second phase compensation capacitor and said second current mirror circuit to provide short-circuiting between said negative power supply and said second connecting node.

3. The display device according to claim 1, wherein said bias control circuit includes:
third and fourth transistors connected in parallel between third and fourth connecting nodes, said third connecting node being connected to said first current mirror circuit and the gate of said first transistor, and said fourth connecting node being connected to said second current mirror circuit and the gate of said second transistor;
a fifth switch connected in series to said third transistor between said third and fourth connecting nodes, said fifth switch being turned off during said switching period to thereby cut off a current path between said third and fourth connecting nodes through said third transistor; and
a sixth switch connected in series to said fourth transistor between said third and fourth connecting nodes, said sixth switch being turned off to thereby cut off a current path between said third and fourth connecting nodes through said fourth transistor.

4. The display device according to claim 1, wherein said bias control circuit includes:
third and fourth transistors connected in parallel between third and fourth connecting nodes, said third connecting node being connected to said first current mirror circuit, and said fourth connecting node being connected to said second current mirror circuit;
a fifth switch connected between said third connecting node and the gate of said first transistor, said fifth switch being turned off during said switching period to cut off a current path between said third connecting node and the gate of said first transistor;
a sixth switch connected between said fourth connecting node and the gate of said second transistor, said sixth switch being turned off during said switching period to cut off a current path between said fourth connecting node and the gate of said second transistor;
a seventh switch connected between said first phase compensation capacitor and said first current mirror circuit, said seventh switch being turned off during said switching period to cut off a current path between said first current mirror circuit and said output terminal; and
an eighth switch connected between said second phase compensation capacitor and said second current mirror circuit, said eighth switch being turned off during said switching period to cut off a current path between said second current mirror circuit and said output terminal.

5. The display device according to claim 1, wherein said output stage circuit further includes:
a first switch connected between the gate and source of said first transistor to provide short-circuiting between the gate and source of said first transistor during said switching period; and
a second switch connected between the gate and source of said second transistor to provide short-circuiting between the gate and source of said second transistor during said switching period, and
wherein said input circuit further includes:
a third switch controlling a bias current fed to said first differential input stage circuit; and
a fourth switch controlling a bias current fed to said second differential input stage circuit.

6. The display device according to claim 5, wherein said third switch is connected between said first differential input stage circuit and said negative power supply, and
wherein said fourth switch is connected between said second differential input stage circuit and said positive power supply.

7. The display device according to claim 5, wherein said bias control circuit includes:
third and fourth transistors connected in parallel between third and fourth connecting nodes, said third connecting node being connected to said first current mirror circuit, and said fourth connecting node being connected to said second current mirror circuit;
a fifth switch connected between said third connecting node and the gate of said first transistor, said fifth switch being turned off during said switching period to cut off a current path between said third connecting node and the gate of said first transistor;
a sixth switch connected between said fourth connecting node and the gate of said second transistor, said sixth switch being turned off during said switching period to cut off a current path between said fourth connecting node and the gate of said second transistor.

8. The display device according to claim 1, wherein the gate of said first transistor is connected to a connecting node between said first phase compensation capacitor and said first current mirror circuit,
wherein the gate of said second transistor is connected to a connecting node between said second phase compensation capacitor and said second current mirror circuit,
wherein said output stage circuit further includes:
a first phase compensation resistor connected in series to said first phase compensation transistor between the gate of said first transistor and said output terminal;
a second phase compensation resistor connected in series to said second phase compensation transistor between the gate of said second transistor and said output terminal;
a first switch connected between the gate and source of said first transistor to provide short-circuiting between the gate and source of said first transistor during said switching period; and
a second switch connected between the gate and source of said second transistor to provide short-circuiting between the gate and source of said second transistor during said switching period.

9. The display device according to claim 8, wherein said bias control circuit includes:
third and fourth transistors connected in parallel between third and fourth connecting nodes, said third connecting node being connected to said first current mirror circuit and the gate of said first transistor, and said fourth connecting node being connected to said second current mirror circuit and the gate of said second transistor;
a third switch connected in series to said third transistor between said third and fourth connecting nodes, said third switch being turned off during said switching period to thereby cut off a current path between said third and fourth connecting nodes through said third transistor; and
a fourth switch connected in series to said fourth transistor between said third and fourth connecting nodes, said fourth switch being turned off during said switching period to thereby cut off a current path between said third and fourth connecting nodes through said fourth transistor.

10. The display device according to claim 8, wherein said bias control circuit includes:
third and fourth transistors connected in parallel between third and fourth connecting nodes, said third connecting node being connected to said first current mirror circuit, and said fourth connecting node being connected to said second current mirror circuit;
a third switch connected between said third connecting node and the gate of said first transistor, said third switch being turned off during said switching period to cut off a current path between said third connecting node and the gate of said first transistor; and
a fourth switch connected between said fourth connecting node and the gate of said second transistor, said fourth switch being turned off during said switching period to cut off a current path between said fourth connecting node and the gate of said second transistor.

11. A differential amplifier, comprising:
an input circuit including a first differential input stage circuit comprising a first transistor pair and a second differential input stage circuit comprising a second transistor pair, said first and second transistor pairs being complementary;
an adder circuit including a first current mirror circuit provided between said first differential input stage circuit and a positive power supply and a second current mirror circuit provided between said second differential input stage circuit and a negative power supply;
an output stage circuit including a first transistor having a source connected to said positive power supply, a second transistor having a source connected to said negative power supply, an output terminal connected to drains of said first and second transistors, a first phase compensation capacitor provided between said first current mirror circuit and said output terminal, and a second phase compensation capacitor provided between said second current mirror circuit and said output terminal; and
a bias control circuit provided between said adder circuit and said output stage circuit to achieve bias control of gates of said first and second transistors,
wherein, during a switching period, said output stage circuit provides short-circuiting between the gate and source of said first transistor and short-circuiting between the gate and source of said second transistor, and charges or discharges said first and second phase compensation capacitors to a certain voltage level, and
wherein said bias control circuit cuts off a current path between the gates of said first and second transistors during said switching period.

12. A data line drive method for a display device including:
a plurality of differential amplifiers associated with a plurality of data lines within a display panel, said plurality of differential amplifiers respectively receiving gray-level voltages which are switched between positive and negative polarities with respect to a reference voltage level and outputting said received gray-level voltages to associated ones of said plurality of data lines; and
an output short-circuiting section providing short-circuiting among said plurality of data lines during a switching period in which polarities of said gray-level voltages to be received by said plurality of differential amplifiers are switched,
each of said plurality of differential amplifiers including:
an input circuit including a first differential input stage circuit comprising a first transistor pair and a second differential input stage circuit comprising a second transistor pair, said first and second transistor pairs being complementary;
an adder circuit including a first current mirror circuit provided between said first differential input stage circuit and a positive power supply and a second current mirror circuit provided between said second differential input stage circuit and a negative power supply;
an output stage circuit including a first transistor having a source connected to said positive power supply, a second transistor having a source connected to said negative power supply, an output terminal connected to drains of said first and second transistors, a first phase compensation capacitor provided between said first current mirror circuit and said output terminal, and a second phase compensation capacitor provided between said second current mirror circuit and said output terminal; and
a bias control circuit provided between said adder circuit and said output stage circuit to achieve bias control of gates of said first and second transistors,
said method comprising:
short-circuiting the gate and source of each of said first and second transistors during said switching period,
charging or discharging said first and second phase compensation capacitors to a certain voltage level during said switching period; and
cutting off a current path between the gates of said first and second transistors during said switching period.

13. The data line drive method according to claim 12, wherein said short-circuiting includes:
short-circuiting the gate and source of said first transistor during said switching period by a first switch connected between the gate and source of said first transistor; and
short-circuiting the gate and source of said second transistor during said switching period by a second switch connected between the gate and source of said second transistor,
wherein said charging or discharging includes:
short-circuiting said positive power supply and a first connecting node of said first phase compensation capacitor and said first current mirror circuit during said switching period by a third switch connected between said positive power supply and said first connecting node;
short-circuiting said negative power supply and a second connecting node of said second phase compensation capacitor and said second current mirror circuit during said switching period by a fourth switch connected between said negative power supply and said second connecting node.

14. The data line drive method according to claim 12, wherein said bias control circuit includes: third and fourth transistors connected in parallel between third and fourth connecting nodes, said third connecting node being connected to said first current mirror circuit and the gate of said first transistor, and said fourth connecting node being connected to said second current mirror circuit and the gate of said second transistor;
wherein said cutting off includes:
cutting off a current path between said third and fourth connecting nodes through said third transistor during said switching period by turning off a fifth switch connected in series to said third transistor between said third and fourth connecting nodes; and
cutting off a current path between said third and fourth connecting nodes through said fourth transistor during said switching period by turning off a sixth switch connected in series to said fourth transistor between said third and fourth connecting nodes.

15. The data line drive method according to claim 12, wherein said bias control circuit includes: third and fourth transistors connected in parallel between third and fourth connecting nodes, said third connecting node being connected to said first current mirror circuit, and said fourth connecting node being connected to said second current mirror circuit,
wherein said cutting off includes:
cutting off a current path between said third connecting node and the gate of said first transistor during said switching period by turning off a fifth switch connected between said third connecting node and the gate of said first transistor;
cutting off a current path between said fourth connecting node and the gate of said second transistor during said switching period by turning off a sixth switch connected between said fourth connecting node and the gate of said second transistor;
cutting off a current path between said first current mirror circuit and said output terminal during said switching period by turning off a seventh switch connected between said first phase compensation capacitor and said first current mirror circuit; and
cutting off a current path between said second current mirror circuit and said output terminal during said switching period by turning off an eighth switch connected between said second phase compensation capacitor and said second current mirror circuit.

16. The data line drive method according to claim 12, further comprising:
controlling a bias current fed to said first differential input stage circuit; and
controlling a bias current fed to said second differential input stage circuit,
wherein said short-circuiting includes:
short-circuiting the gate and source of said first transistor during said switching period by a first switch connected between the gate and source of said first transistor; and
short-circuiting the gate and source of said second transistor during said switching period by a first switch connected between the gate and source of said second transistor.

17. The data line drive method according to claim 16, wherein said controlling the bias current fed to said first differential input stage circuit includes:
controlling the bias current fed to said first differential input stage circuit by a third switch connected between said first differential input stage circuit and said negative power supply, and
wherein said controlling the bias current fed to said second differential input stage circuit includes:
controlling the bias current fed to said second differential input stage circuit by a fourth switch connected between said second differential input stage circuit and said positive power supply.

18. The data line drive method according to claim 16, wherein said bias control circuit includes: third and fourth transistors connected in parallel between third and fourth connecting nodes, said third connecting node being connected to said first current mirror circuit, and said fourth connecting node being connected to said second current mirror circuit;
wherein said cutting off includes:
cutting off a current path between said third connecting node and the gate of said first transistor during said switching period by turning off a fifth switch connected between said third connecting node and the gate of said first transistor; and
cutting off a current path between said fourth connecting node and the gate of said second transistor during said switching period by turning off a sixth switch connected between said fourth connecting node and the gate of said second transistor.

19. The data line drive method according to claim 12, wherein the gate of said first transistor is connected to a connecting node between said first phase compensation capacitor and said first current mirror circuit,
wherein the gate of said second transistor is connected to a connecting node between said second phase compensation capacitor and said second current mirror circuit,
wherein said output stage circuit further includes:
a first phase compensation resistor connected in series to said first phase compensation transistor between the gate of said first transistor and said output terminal; and
a second phase compensation resistor connected in series to said second phase compensation transistor between the gate of said second transistor and said output terminal,
wherein said short-circuiting includes:
short-circuiting the gate and source of said first transistor during said switching period by a first switch connected between the gate and source of said first transistor; and
short-circuiting the gate and source of said second transistor during said switching period by a second switch connected between the gate and source of said second transistor.

20. The data line drive method according to claim 19, wherein said bias control circuit includes: third and fourth transistors connected in parallel between third and fourth connecting nodes, said third connecting node being connected to said first current mirror circuit and the gate of said first transistor, and said fourth connecting node being connected to said second current mirror circuit and the gate of said second transistor;
wherein said cutting off includes:
cutting off a current path between said third and fourth connecting nodes through said third transistor during said switching period by turning off a third switch connected in series to said third transistor between said third and fourth connecting nodes; and
cutting off a current path between said third and fourth connecting nodes through said fourth transistor during said switching period by turning off a fourth switch connected in series to said fourth transistor between said third and fourth connecting nodes.

21. The data line drive method according to claim 19, wherein said bias control circuit includes: third and fourth transistors connected in parallel between third and fourth connecting nodes, said third connecting node being connected to said first current mirror circuit, and said fourth connecting node being connected to said second current mirror circuit;
wherein said cutting off includes:
cutting off a current path between said third connecting node and the gate of said first transistor during said switching period by turning off a third switch connected between said third connecting node and the gate of said first transistor; and
cutting off a current path between said fourth connecting node and the gate of said second transistor during said switching period by turning off a fourth switch connected between said fourth connecting node and the gate of said second transistor.
